(19) United States
(12) Patent Application Publication
(10) Pub. No.: US 2017/0097570 A1
(43) Pub. Date: Apr. 6, 2017

(54) RESIST PATTERNING METHOD, LATENT RESIST IMAGE FORMING DEVICE, AND RESIST MATERIAL

(71) Applicant: OSAKA UNIVERSITY, Osaka (JP)

(72) Inventor: Seiichi TAGAWA, Suita-shi (JP)

(73) Assignee: OSAKA UNIVERSITY, Osaka (JP)

(21) Appl. No.: 15/312,470

(22) PCT Filed: May 21, 2015
(86) PCT No.: PCT/JP2015/064649

§ 371 Date: Nov. 18, 2016

(30) Foreign Application Priority Data
May 21, 2014 (JP) 2014-105617

(51) Int. Cl. G03F 7/20; H01L 21/027; G03F 7/039; G03F 7/16; G03F 7/11; G03F 7/038; G03F 7/004; G03F 7/26

(52) U.S. Cl. CPC G03F 7/2022; G03F 7/0045; H01L 21/0274; G03F 7/2004; G03F 7/26; G03F 7/16; G03F 7/11; G03F 7/038; G03F 7/039

(57) ABSTRACT

A resist patterning method according to the present invention includes a resist layer forming step, a patterned exposure step, a flood exposure step, and a developing step. In the resist layer forming step, a resist layer containing a base resin, a sensitizer precursor, an acid generator, and a base generator is formed on a substrate. In the patterned exposure step, patterned exposure is performed on the resist layer to produce a sensitizer from the sensitizer precursor. In the flood exposure step, flood exposure is performed on the resist layer in which the sensitizer has been produced to produce an acid from the acid generator and produce a base from the base generator after the patterned exposure. In the developing step, the resist layer is developed after the flood exposure.

### TECHNICAL FIELD

The present invention relates to resist patterning methods, latent resist image forming devices, and resist materials.

### BACKGROUND ART

Miniaturization of semiconductor devices has progressed over years for achieving higher integration and higher speed of semiconductor devices. Accordingly, there has been a demand for finer patterns in photolithographic steps for semiconductor devices. As a technique to achieve a finer pattern, decreasing the wavelength of an exposure source has been contemplated.

For example, a technique using extreme ultraviolet light (EUV, wavelength: 13.5 nm) has recently undergone development as being promising in production of next-generation semiconductor devices. However, it is difficult to develop a light source device with a power (250 W) for a light source in a light exposure device that is needed to apply the device to mass production. It is therefore still necessary to perform light exposure for a long period of time in order to form a latent pattern image. Meanwhile, an electron beam direct writing method uses an electron beam (EB) having a small beam diameter and therefore allows formation of a fine pattern with high dimensional precision but takes more time to write a more complicated and larger-area pattern. As described above, the problem with the exposure techniques using extreme ultraviolet light and an electron beam is that the throughput is low while a fine pattern can be formed.

In order to make up for the insufficient light source intensity, improvement of the sensitivity of resist materials is being promoted so that the period of time of exposure is reduced as much as possible. For example, a resist composition disclosed in Patent Literature 1 is composed of a specified resin and a specified compound, and thus improved in resist sensitivity and resolution.

### CITATION LIST

### Patent Literature

[Patent Literature 1]

Japanese Patent Application Laid-Open Publication No. 2002-174894

### SUMMARY OF INVENTION

### Technical Problem

However, there is a trade-off between three important properties of a resist, that is, the sensitivity, the resolution, and the line width roughness (LWR); merely increasing the sensitivity of a resist leads to decrease in the resolution and increase in the LWR. Accordingly, conventional techniques have a limit to increasing the sensitivity of a resist without decreasing the resolution and without increasing the line width roughness, and therefore are unable to sufficiently solve the problem of low throughput. Furthermore, roughness of a pattern due to photon shot noise has recently been considered more problematic and important than the trade-off, which used to be the most important problem. However, no solution therefore has been found so far.

In view of the above-described problems, the present invention has been made to provide a resist patterning method, a latent resist image forming device, and a resist material that can improve the sensitivity of resist layers and reduce roughness due to photon shot noise while solving the trade-off between the sensitivity, the resolution, and the line width roughness (LWR).

### Solution to Problem

A resist patterning method according to the present invention includes: a resist layer forming step of forming, on a substrate, a resist layer containing a base resin, a sensitizer precursor, an acid generator, and a base generator; a patterned exposure step of performing patterned exposure on the resist layer to produce a sensitizer from the sensitizer precursor; a flood exposure step of performing flood exposure on the resist layer in which the sensitizer has been produced to produce an acid from the acid generator and produce a base from the base generator after the patterned exposure; and a developing step of developing the resist layer after the flood exposure.

According to an embodiment, the flood exposure step includes: a first flood exposure step of performing first flood exposure through which the sensitizer is excited, and the acid is produced through a reaction between the excited sensitizer and the acid generator; and a second flood exposure step of performing second flood exposure through which the base is produced from the base generator.

According to an embodiment, in the patterned exposure step, the sensitizer is produced through structural transformation of the sensitizer precursor as a result of the patterned exposure, or the sensitizer is produced through a reaction between an electron generated in the resist layer and the sensitizer precursor.

According to an embodiment, in the patterned exposure step, the sensitizer is produced through a reaction between the sensitizer precursor and an acid produced from the acid generator through the patterned exposure, and in the flood exposure step, the acid is produced from the acid generator with use of the sensitizer excited through the flood exposure.

According to an embodiment, in the patterned exposure step, the sensitizer is produced in association with diffusion of the acid.

According to an embodiment, in the patterned exposure step, the sensitizer precursor has either or both of sensitizing action on a reaction that produces the sensitizer from the sensitizer precursor and sensitizing action on a reaction that produces the acid from the acid generator.

According to an embodiment, in the resist layer forming step, the resist layer contains a base component.

According to an embodiment, in the patterned exposure step, spatial distribution of the sensitizer is controlled by controlling a diffusion coefficient of the acid and a diffusion coefficient of the base component, and in the flood exposure step, spatial distribution of the acid is controlled based on the spatial distribution of the sensitizer.

According to an embodiment, in the patterned exposure step, the acid reacts with the base component to newly produce the acid generator.

According to an embodiment, in the patterned exposure step, the acid reacts with the base component to produce a different acid generator than the acid generator contained in the resist layer.

According to an embodiment, in the patterned exposure step, the base component is decomposed through the patterned exposure.

According to an embodiment, in the resist layer forming step, the resist layer contains a base component, and in at least one of the patterned exposure step and the first flood exposure step, the base component is decomposed through at least one of the patterned exposure and the first flood exposure.

According to an embodiment, in the flood exposure step, the sensitizer is excited by the flood exposure, and the base component is decomposed by the excited sensitizer.

According to an embodiment, in the resist layer forming step, the resist layer contains a radical generating component, and in the patterned exposure step, the sensitizer is produced from the sensitizer precursor with use of a radical produced from the radical generating component through the patterned exposure.

According to an embodiment, in the patterned exposure step, the sensitizer is produced in association with diffusion of the radical.

According to an embodiment, in the flood exposure step, the acid is produced in association with either or both of electron transfer and energy transfer from the sensitizer in an excited state to the acid generator.

According to an embodiment, in the flood exposure step, the acid has a substantially constant peak concentration throughout a region that is, of the resist layer, subjected to both the patterned exposure and the flood exposure.

According to an embodiment, in the flood exposure step, the base has a substantially constant peak concentration throughout a region on which, of the resist layer, the flood exposure has been performed but the patterned exposure has not been performed.

According to an embodiment, the resist patterning method further includes a modification step of performing a modification treatment for transforming the resist layer from a positive type to a negative type or vice versa after the flood exposure step.

According to an embodiment, in the resist layer forming step, the resist layer is a non-chemically amplified resist layer.

According to an embodiment, the resist patterning method further includes an underlayer forming step of forming an underlayer between the resist layer and the substrate.

According to an embodiment, the resist patterning method further includes a topcoat forming step of forming a topcoat on the resist layer.

A latent resist image forming device according to the present invention includes: a patterned exposure device configured to perform patterned exposure on a resist layer containing a base resin, a sensitizer precursor, an acid generator, and a base generator to produce a sensitizer from the sensitizer precursor; and a flood exposure device configured to perform flood exposure on the resist layer in which the sensitizer has been produced to produce an acid from the acid generator and produce a base from the base generator.

According to an embodiment, the flood exposure device includes: a first flood exposure device configured to cause the acid to be produced from the acid generator; and a second flood exposure device configured to cause the base to be produced from the base generator.

According to an embodiment, the patterned exposure device causes the sensitizer to be produced through a reaction between the sensitizer and an acid produced from the acid generator through the patterned exposure, and the flood exposure device causes the acid to be produced from the acid generator with use of the sensitizer through the flood exposure.

According to an embodiment, the resist layer contains a radical generating component, and the patterned exposure device causes the sensitizer to be produced from the sensitizer precursor with use of a radical produced from the radical generating component through the patterned exposure.

According to an embodiment, the flood exposure device continues the flood exposure until the acid has a substantially constant peak concentration throughout a region that is, of the resist layer, subjected to both the patterned exposure and the flood exposure.

According to an embodiment, the flood exposure device continues the flood exposure until the base has a substantially constant peak concentration throughout a region on which, of the resist layer, the flood exposure has been performed but the patterned exposure has not been performed.

A resist material according to the present invention includes a resist composition containing a base resin, a sensitizer precursor, an acid generator, and a base generator.

According to an embodiment, the resist composition contains a base component.

According to an embodiment, the resist composition contains a radical scavenger component.

### Advantageous Effects of Invention

The present invention can improve the sensitivity of resist layers and reduce roughness due to photon shot noise while solving the trade-off between the sensitivity, the resolution, and the line width roughness.

### BRIEF DESCRIPTION OF DRAWINGS

FIGS. 1A to 1D are schematic diagrams each illustrating a process of an embodiment of a resist patterning method according to the present invention.

FIGS. 2A and 2B are schematic diagrams respectively illustrating concentration distribution in a resist layer after patterned exposure and concentration distribution in the resist layer after flood exposure.

FIGS. 3A to 3E are schematic diagrams each illustrating a process of a resist patterning method according to an embodiment of the present invention.

FIGS. 4A, 4B, and 4C are schematic diagrams respectively illustrating concentration distribution in a resist layer after patterned exposure, concentration distribution in the resist layer after first flood exposure, concentration distribution in the resist layer before and after second flood exposure in an embodiment of the present invention.

FIGS. 5A and 5B show schematic absorption wavelength spectra of a sensitizer precursor, a sensitizer, and a base generator in an embodiment of the present invention.

FIG. 6 is a schematic diagram illustrating concentration distribution in a resist layer before and after the patterned exposure in an embodiment of the present invention.

FIG. 7 is a schematic diagram illustrating concentration distribution in a resist layer before and after the patterned exposure in an embodiment of the present invention.

FIG. 8 is a schematic diagram illustrating concentration distribution in the resist layer before and after the first flood exposure in an embodiment of the present invention.

FIG. 9 shows schematic absorption wavelength spectra of an acid generator, a sensitizer precursor, a sensitizer, and a base generator in an embodiment of the present invention.

FIGS. 10A to 10D are schematic diagrams each illustrating a process of a resist patterning method according to an embodiment of the present invention.

FIG. 11 is a schematic diagram illustrating concentration distribution in the resist layer before and after the patterned exposure in an embodiment of the present invention.

FIGS. 12A and 12B are schematic diagrams illustrating concentration distribution in the resist layer before and after the patterned exposure in an embodiment of the present invention.

FIGS. 13A and 13B are schematic diagrams each illustrating concentration distribution in the resist layer before and after the patterned exposure in an embodiment of the present invention.

FIGS. 14A to 14D are schematic diagrams each illustrating a process of a resist patterning method according to an embodiment of the present invention.

FIGS. 15A to 15D are schematic diagrams each illustrating a process of a resist patterning method according to an embodiment of the present invention.

FIG. 16 is a schematic diagram of an embodiment of a latent resist image forming device according to the present invention.

FIG. 17 is a schematic diagram of a latent resist image forming device according to an embodiment of the present invention.

FIG. 18 is a schematic diagram of a latent resist image forming device according to an embodiment of the present invention.

FIGS. 19A and 19B are diagrams each showing an SEM image of the resist layer subjected to the patterned exposure and the flood exposure.

FIGS. 20A and 20B are diagrams each showing an SEM image of the resist layer on which the patterned exposure has been performed but the flood exposure has not been performed thereafter.

### DESCRIPTION OF EMBODIMENTS

Hereinafter, embodiments of a resist patterning method, a latent resist image forming device, and a resist material according to the present invention will be described with reference to the drawings. However, the present invention is not limited to the following embodiments.

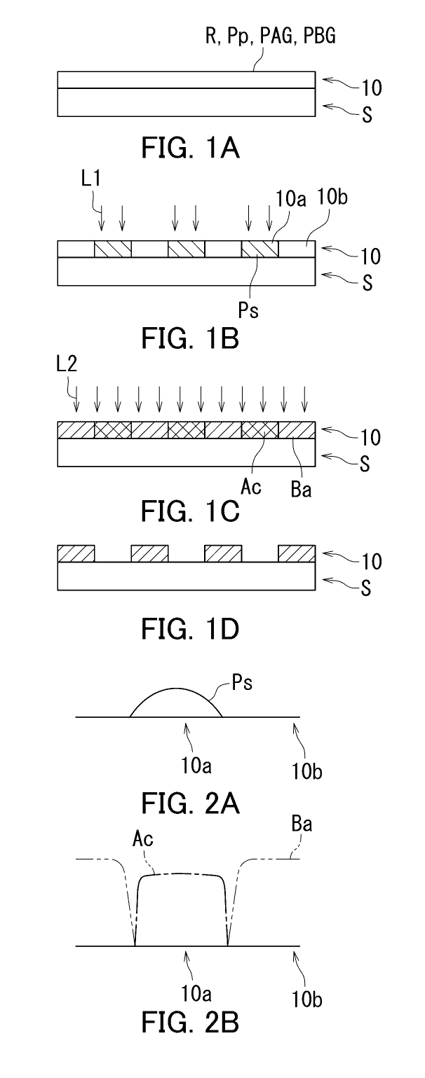

First, an embodiment of the resist patterning method and the resist material according to the present invention will be described with reference to FIGS. 1A to 1D and 2A to 2B. Note that resist layers including resist materials are classified into the following types: positive resist layers in which a portion thereof that is exposed to light becomes soluble in a developing solution; and negative resist layers in which a portion thereof that is exposed to light becomes insoluble in a developing solution. The following description takes a positive resist layer as an example. The resist layer may be a chemically amplified resist layer containing an acid generator that generates an acid upon exposure to light and a base material (base resin) whose solubility to a developing solution is changed by the action of the acid.

FIGS. 1A to 1D are schematic diagrams each illustrating a process of the embodiment of the resist patterning method according to the present invention. FIGS. 2A and 2B respectively illustrate concentration distribution in a resist layer 10 after patterned exposure and concentration distribution in the resist layer 10 after flood exposure.

First, as illustrated in FIG. 1A, the resist layer 10 is formed on a substrate S. For example, the substrate S (for example, wafer) is prepared, and a resist material dissolved in a liquid is applied onto the substrate S and pre-baked to form the resist layer 10. Typically, a photolithography target (for example, a semiconductor layer or an insulating layer) is formed on a surface of the substrate S.

The resist layer 10 contains a base resin R, a sensitizer precursor Pp, an acid generator PAG (photoacid generator: PAG), and a base generator PBG (photobase generator: PBG). The resist layer 10 may be formed directly on the substrate S or may be formed on an underlayer disposed over the substrate S. In the resist layer 10, for example, the sensitizer precursor Pp is contained in an amount of at least 0.1 parts by mass and no greater than 40 parts by mass, the acid generator PAG is contained in an amount of at least 0.1 parts by mass and no greater than 40 parts by mass, and the base generator PBG is contained in an amount of greater than 0 parts by mass and no greater than 40 parts by mass, relative to 100 parts by mass of the base resin R.

The base resin R is for example a methyl methacrylate-based polymer (hereinafter, referred to as “MMA”). An intermediate, a radical, an ion (cation or anion), and the like are involved in a chemical reaction caused by at least one of patterned exposure L1 and flood exposure L2 to be described later. The MMA resin tends not to dissipate an intermediate, a radical, and an ion. The base resin R may contain a polyhydroxystyrene resin (PHS resin). Alternatively, the base resin R may be a mixture of an MMA resin and a PHS resin.

Alternatively, the base resin R may be a phenolic resin or any of various resins having an acetal-type protective group. In the case of EUV exposure or EB exposure, protons are generated mainly from the base resin R, move within the base resin R or among molecules of the base resin R, and react with anions generated through dissociation of the acid generator PAG to produce an acid. The base resin R may contain a low-molecular compound as well as a high-molecular compound. However, it is preferable that protons generated from a low-molecular compound move among molecules of the base resin and react with anions generated through dissociation of the acid generator PAG to produce an acid. Furthermore, the base resin R may be a resin from which protons that move within the base resin R or among molecules of the base resin R are not generated. Alternatively, the base resin R may be an inorganic substance. Note that EUV or EB beam irradiation causes a radiochemical reaction in the resist layer 10, whereas ArF laser or KrF laser beam irradiation causes a photochemical reaction in the resist layer 10. As mentioned above, acid formation reactions that are initiated from an excited state of the acid generator PAG differ depending on the type of the source of a beam to irradiate.

The base resin R may be decomposed by at least one of the patterned exposure L1 and the flood exposure L2 to generate an intermediate, a radical, and an ion. In particular, use of an electron beam or an EUV beam as a beam for the patterned exposure L1 allows the base resin R to be decomposed relatively easily.

The sensitizer precursor Pp may be of acetal type or alcohol type. In a configuration in which the sensitizer precursor Pp is of acetal type, the acetal compound may be a compound obtained from an aldehyde or a compound obtained from a ketone. Other than an acetal, the sensitizer precursor Pp may alternatively be a ketal or a hemiacetal (semiketal). For example, the sensitizer precursor Pp is a dimethoxy benzhydrol derivative (DOBzMM).

The sensitizer precursor Pp may be mixed in the base resin R. Alternatively, the sensitizer precursor Pp may be bound to another component of the resist layer 10. For example, the sensitizer precursor Pp is bound to the base resin R.

In a configuration in which the sensitizer precursor Pp is of alcohol type, the resist layer 10 contains a radical generating component. The radical generating component may be mixed in the base resin R. Alternatively, the radical generating component may be bound to another component of the resist layer 10. For example, the radical generating component may be bound to the base resin R or bound to the acid generator PAG.

A radical produced from the radical generating component in the resist layer 10 causes a sensitizer Ps to be produced from the sensitizer precursor Pp. The sensitizer precursor Pp for example includes at least one of alcohol-type sensitizer precursors such as bis(4-methoxyphenyl)methanol (DOMeBzH) and trimethoxy benzhydrol (TriOMeBzH). Alternatively, the sensitizer precursor Pp may be a mixture of an acetal-type sensitizer precursor and an alcohol-type sensitizer precursor.

The acid generator PAG may for example be iodonium salt (R₂IX)-based diphenyliodonium perfluorobutanesulfonate (DPI-PFBS) or sulfonium salt (R₃SX)-based triphenylsulfonium perfluorobutanesulfonate (TPS-PFBS). Alternatively, the acid generator PAG may be an iodonium salt such as PBpS-PFBS.

The acid generator PAG is preferably a bulky acid generator having a low diffusion coefficient. However, the acid generator PAG may be bound to the base resin R. The acid generator PAG is preferably an acid generator that efficiently undergoes electron transfer from the sensitizer Ps in an excited state. Furthermore, the concentration of the acid generator PAG is preferably so high that smooth electron transfer occurs. A single compound may function both as the sensitizer precursor Pp and as the acid generator PAG.

The base generator PBG may be of nonionic type or ionic type. The base generator PBG of nonionic type is for example 9-anthrylmethyl N,N-diethylcarbamate. The base generator PBG of ionic type is for example cyclohexylammonium 2-(3-benzoylphenyl) propionate or dicyclohexylammonium 2-(3-benzoylphenyl) propionate. A base Ba produced from the base generator PBG preferably has a low diffusion coefficient.

Next, the patterned exposure L1 is performed on the resist layer 10 as illustrated in FIG. 1B. Regions 10a of the resist layer 10 are irradiated with the beam for the patterned exposure L1, but regions 10b of the resist layer 10 is not irradiated with the beam.

The patterned exposure L1 imparts energy to the regions 10a of the resist layer 10. In a configuration in which a pattern of the patterned exposure L1 is fine in order to achieve a high resolution, an energy intensity distribution may be approximated as a sine wave. The energy imparted to the regions 10a excites or ionizes a component of the resist layer 10 to produce an active substance, and the sensitizer Ps is produced from the sensitizer precursor Pp in the resist layer 10. FIG. 2A illustrates concentration distribution of the sensitizer Ps in one region 10a. The patterned exposure L1 may cause production of an acid Ac from the acid generator PAG as well as production of the sensitizer Ps. Concentration distribution of the acid Ac in each region 10a is for example substantially similar to the concentration distribution of the sensitizer Ps.

Preferably, the environment surrounding the resist layer 10 is for example an atmosphere that can control decay of the acid and the radical involved in the production of the sensitizer Ps. The environment that can control decay of the acid and the radical involved in the production of the sensitizer Ps may be a basic substance-free inert gas atmosphere or a vacuum atmosphere. Additionally or alternatively, a topcoat layer that insulates basic substances and/or oxygen may be provided on the resist layer 10. In a configuration in which the environment surrounding the resist layer 10 is an inert gas atmosphere, nitrogen gas, helium gas, or argon gas is for example used as the inert gas. In such a configuration, the atmosphere may be under reduced or increased pressure. In a configuration in which the environment surrounding the resist layer 10 is a vacuum atmosphere, at least an area surrounding the resist layer 10 is under vacuum. Preferably, the area surrounding the resist layer 10 is at a vacuum of no greater than 1 Pa. In an inert gas atmosphere environment or a vacuum atmosphere environment, decay of the acid and the radical involved in the production of the sensitizer Ps in the resist layer 10 is inhibited.

In a configuration in which the sensitizer precursor Pp is of acetal type, the patterned exposure L1 is preferably performed in an atmosphere that prevents acid inactivation by setting up an exposure device in a clean room and inserting a base removal filter into the exposure device, as in the case of chemically amplified resists that are mainly used in recent semiconductor mass production processes. In a configuration in which the sensitizer precursor Pp is of alcohol type, the patterned exposure L1 is preferably performed in a vacuum or inert atmosphere that prevents acid inactivation.

The beam for the patterned exposure L1 is for example extreme ultraviolet light (EUV), an electron beam (EB), ArF excimer laser, and KrF excimer laser. A topcoat layer that insulates basic substances and/or oxygen may be provided on the resist layer 10.

Next, the flood exposure L2 is performed on the resist layer 10 as illustrated in FIG. 1C. The flood exposure L2 imparts energy to the entire resist layer 10 in which the sensitizer Ps has been produced. As a result of the imparted energy, the acid Ac is produced from the acid generator PAG in the regions 10a, and the base Ba is produced from the base generator PBG in the entire resist layer 10 as illustrated in FIG. 2B. Even though the regions 10b, in which the sensitizer Ps is not produced, are irradiated with a beam for the flood exposure L2, neither the acid generator PAG nor the sensitizer precursor Pp in the regions 10b substantially reacts.

The sensitizer Ps for example transitions into an excited state as a result of the flood exposure L2. In the regions 10a, the acid Ac is produced from the acid generator PAG with use of the sensitizer Ps. As mentioned above, the base Ba may be produced directly from the base generator PBG in the entire resist layer 10 through the flood exposure L2. Alternatively, the base Ba may be produced from the base generator PBG with use of the sensitizer Ps through the flood exposure L2.

In a configuration in which the acid Ac is produced from the acid generator PAG with use of the sensitizer Ps, electron transfer from the sensitizer Ps in the excited state to the acid generator PAG causes the acid generator PAG to be decomposed through a dissociative electrophilic addition reaction. As a result, the acid Ac and the sensitizer Ps that is unexcited are newly produced.

The production of the acid Ac and the sensitizer Ps is continued until the acid generator PAG and the sensitizer precursor Pp are consumed substantially completely as long as the flood exposure L2 is continued in the regions 10a including the sensitizer Ps and the acid generator PAG.

Typically, a beam intensity for the flood exposure L2 is higher than a beam intensity for the patterned exposure L1. The flood exposure L2 can be performed with a less costly light source than that for the patterned exposure L1. Typically, the beam that is used for the flood exposure L2 has a longer wavelength than the beam for the patterned exposure L1. However, the present invention is not limited to such a configuration, and the beam that is used for the flood exposure L2 may have a shorter wavelength than the beam for the patterned exposure L1. For example, a UV beam light source may be used as a light source for the flood exposure L2. In a configuration in which the resist layer 10 is a positive resist layer, a latent image that allows the regions 10a of the resist layer 10 to be removed is formed.

Preferably, the entire resist layer 10 is irradiated with the beam for the flood exposure L2. However, a partial area of the resist layer 10 may be irradiated with the beam for the flood exposure L2.

A commonly performed treatment may be given to the resist layer 10 after the flood exposure L2 is performed. For example, a thermal treatment (post exposure bake: PEB) may be performed after the flood exposure L2. The thermal treatment may for example be pulse thermal treatment. The thermal treatment causes an acid diffusion reaction. The thermal treatment is for example performed at a temperature of at least 100° C. and no greater than 110° C. Furthermore, a modification treatment may be performed for transforming the resist layer 10 from a positive type to a negative type or vice versa after the flood exposure L2.

Next, the resist layer 10 is developed as illustrated in FIG. 1D. As a result of the developing, the regions 10a in which the acid Ac has been produced (regions where the latent image has been formed) are removed by being dissolved in a developing solution. Through the above, the resist layer 10 having a pattern according to a pattern shape of the patterned exposure L1 can be formed. If necessary, pre-baking for heating the resist layer 10 may be performed before the developing.

The resist material according to the present embodiment includes a resist composition containing the base resin R, the sensitizer precursor Pp, the acid generator PAG, and the base generator PBG. When the resist composition in the resist material according to the present embodiment is irradiated with the beam for the patterned exposure L1, the sensitizer Ps that exhibits significant absorption with respect to a beam having a different wavelength from the wavelength of the beam for the patterned exposure L1 is produced from the sensitizer precursor Pp. The sensitizer Ps is produced in a pattern shape in accordance with the irradiation with the beam for the patterned exposure L1. Upon irradiation with the beam for the flood exposure L2, the sensitizer Ps absorbs the beam for the flood exposure L2 to cause a reaction. For example, the acid Ac is produced from the acid generator PAG with use of the sensitizer Ps, and thus a predetermined latent image pattern can be readily formed. The irradiation with the beam for the flood exposure L2 also causes production of the base Ba from the base generator PBG in the resist layer 10.

According to the present embodiment, the flood exposure L2 is performed to excite the sensitizer Ps to cause production of the acid Ac from the acid generator PAG after the patterned exposure L1 is performed to cause production of the sensitizer Ps in the regions 10a of the resist layer 10. Even if a low-power light source is used as a light source of the beam for the patterned exposure L1, therefore, a latent image in an adequate pattern shape can be formed. For example, a latent image can be formed in the regions 10a of the resist layer 10 by irradiating the regions 10a using an EUV beam as the beam for the patterned exposure L1, and subsequently irradiating the resist layer 10 using a UV beam as the beam for the flood exposure L2. In such a case, high throughput can be achieved even with a low-power light source, because the time of the EUV irradiation can be shortened.

Furthermore, according to the present embodiment, the acid Ac is produced in the regions 10a, and the base Ba is produced in the entire resist layer 10. Therefore, the acid Ac is present in the regions 10a and the base Ba is present in the regions 10b at room temperature before the PEB even though the acid Ac in the regions 10a is reduced as a result of a portion thereof being neutralized with the base Ba. Reduction in resolution due to temperature rise and diffusion of the acid Ac as a result of the PEB can be inhibited by the base Ba that is present in the regions 10b.

Furthermore, according to the present embodiment, the base generator PBG in the regions 10b is completely consumed and the base Ba produced from the base generator PBG exhibits a substantially constant peak concentration as illustrated in FIG. 2B as a result of the flood exposure L2 being continued for a sufficient period of time. In the regions 10a, the base Ba produced from the base generator PBG in the regions 10a reacts with the acid Ac to reduce the concentration of the acid Ac. In general, the acid Ac and the base Ba have a very low diffusion coefficient at room temperature. Accordingly, the peak concentration of the acid Ac and the peak concentration of the base Ba are each substantially constant. The concentration of the acid Ac and the concentration of the base Ba exhibit very steep gradients at boundaries between the regions 10a and the regions 10b.

Note that a large chemical gradient magnitude can be obtained through a reaction after the PEB when the acid Ac and the base Ba have a low diffusion coefficient at a PEB temperature. The LWR is inversely proportional to the chemical gradient magnitude. Likewise, the LWR due to photon shot noise is inversely proportional to the chemical gradient magnitude. According to the above-described process, therefore, the LWR due to photon shot noise can be significantly reduced.

This relationship is well known and formulated as shown below.

LWR∝constant/dm/dx σ_{LWR}∝σₘ/dm/dx

In the formulae, σ represents standard deviation value, m represents concentration of a chemical substance after reaction that is normalized to the substance concentration before reaction, x represents position of the resist layer, and dm/dx represents chemical gradient. Reaction variability increases and therefore σₘ increases with decrease in the number of photons. Since a very large chemical gradient dm/dx can be obtained according to the present embodiment, the standard deviation value of the LWR can be reduced even if σₘ is large.

Thus, according to the present embodiment, the trade-off between the sensitivity, the resolution, and the line width roughness (LWR) can be solved, and therefore the sensitivity of the resist layer 10 can be increased while maintaining the pattern resolution. Furthermore, according to the present embodiment, photon shot noise, which has recently been considered a bigger problem than the trade-off, can be significantly improved. As a result, the throughput in the exposure process can be improved, and significant cost reduction for the exposure system can be achieved. Furthermore, since a low-power light source can be used, the lives of consumable parts of the light source device and the exposure device can be extended, and the maintenance cost and the operation cost can be significantly reduced. As described above, the present embodiment can reduce the LWR due to photon shot noise and improve the resist sensitivity while solving the trade-off between the sensitivity, the resolution, and the line width roughness (LWR).

It is generally known to add in advance a great amount of base to a resist material to neutralize excess acid in order that the acid is formed to have a sharp concentration distribution. According to this technique, the acid can be formed to have a concentration distribution that is sharp to some degree. However, in a configuration in which a fine pattern of no greater than several tens of nanometers (for example, no greater than 5 nm to 15 nm) is to be formed, merely adding a great amount of base leads to production of an insufficient amount of acid, making it impossible to form a suitable concentration of acid for such a fine pattern. As a result, the LER and the photon shot noise cannot be improved. In contrast, the present embodiment can produce the base Ba in the regions 10b through the flood exposure L2, and thus the acid Ac can have a sharp concentration distribution. It is therefore possible to increase the sensitivity while reducing the LER and the photon shot noise.

Bis(4-methoxyphenyl)methanol (DOMeBzH) may for example be used as the sensitizer precursor Pp. In this case, the patterned exposure L1 causes ionization of the resist material and thus production mainly of a polymer radical cation (RH^{+•}) and an electron (e⁻). The polymer radical cation (RH^{+•}) reacts with a polymer (RH) to be separated into a radical P^{•} and a cation (RH(H⁺)).

Subsequently, the electron (e⁻) reacts with the acid generator (PAG), and thus a neutral molecule (RI), a radical (R^{•}), and an anion (X⁻) are produced. Furthermore, the cation (RH(H⁺)) reacts with the anion (X⁻), and thus a polymer (RH) and an acid (HX) are produced. The radical (R^{•}) reacts with DOMeBzH, which is the sensitizer precursor Pp, and thus a radical (DOMeBzH^{•}) is produced. This radical reacts with the acid generator (PAG) to cause electron transfer, and thus a cation (DOMeBzH⁺) is produced. A proton is transferred from the cation (DOMeBzH⁺) to the anion, and thus DOMeBzO, which is the sensitizer Ps, and the acid (HX) are produced.

Next, the flood exposure L2 is performed to excite the sensitizer Ps (DOMeBzO). An electron is transferred from the excited sensitizer Ps (DOMeBzO) to the acid generator (PAG), and thus a radical cation of the sensitizer Ps (DOMeBzO^{•+}), a neutral molecule (RI), a radical (R^{•}), and an anion (X⁻) are produced. The flood exposure L2 also causes similar reactions in the regions 10a to the reactions caused by the patterned exposure L1, and thus a chain reaction occurs, producing the acid Ac efficiently. Furthermore, the flood exposure L2 causes production of the base Ba from the base generator PBG (for example, base generator of nonionic type or ionic type described above) over the entire resist layer 10. In the regions 10a of the resist layer 10, however, the amount of the acid Ac produced is greater than the amount of the base Ba. That is, the acid Ac is present but little base Ba is present in the regions 10a. In the regions 10b, in contrast, substantially no acid Ac is produced and the base Ba is present.

Then, the resist layer 10 is developed, and thus the regions 10a in which the acid Ac has been produced (regions where the latent image has been formed) can be removed. As described above, the resist layer 10 may be formed into a predetermined pattern shape with use of a radical.

In the description given above with reference to FIGS. 1A to 1D, the base Ba is produced from the base generator PBG through the flood exposure L2. However, the present invention is not limited to such a configuration. The base Ba may be produced from the base generator PBG also through the patterned exposure L1 as well as through the flood exposure L2.

In the description given above with reference to FIGS. 1A to 1D, the patterned exposure L1 and the flood exposure L2 are each performed once. However, the present invention is not limited to such a configuration. The patterned exposure L1 and the flood exposure L2 may be performed two or more times. For example, the flood exposure L2 may be performed two or more times.

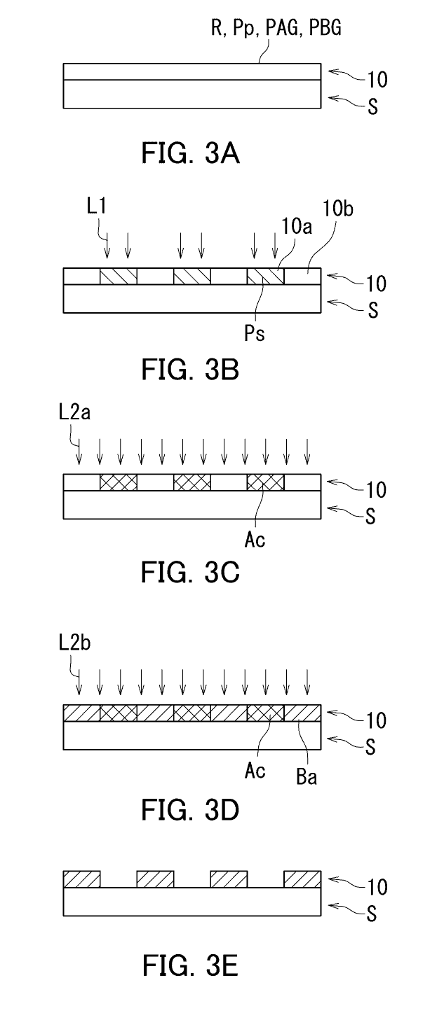

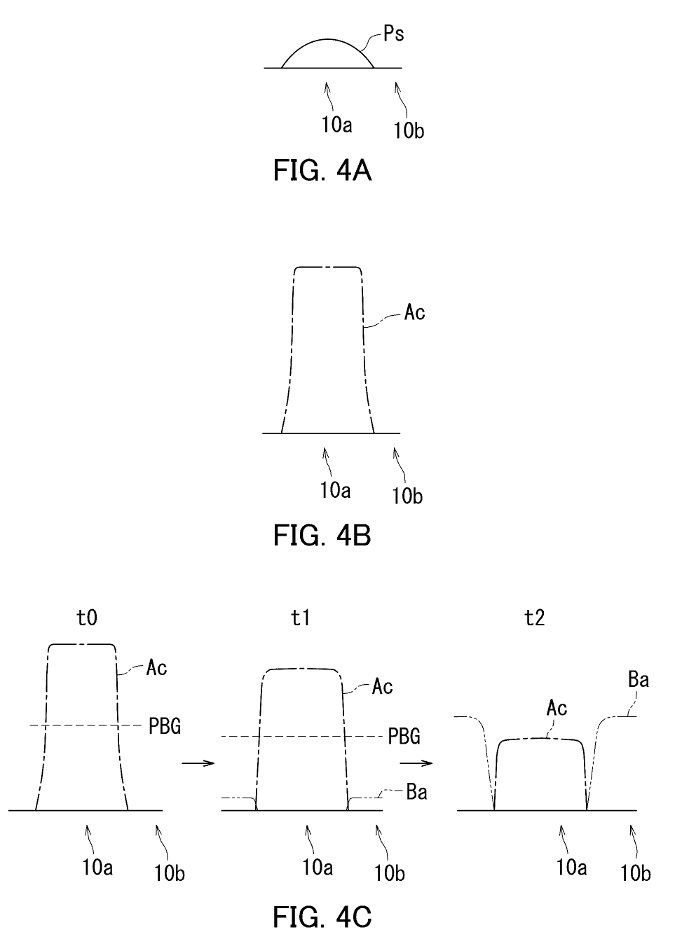

The following describes a resist patterning method and a resist material according to an embodiment of the present invention with reference to FIGS. 3A to 3E and 4A to 4C. The resist patterning method according to the present embodiment is similar to the resist patterning method and the resist material described above with reference to FIGS. 1A to 1D and 2A to 2B except that the flood exposure is performed twice. Accordingly, redundant description thereof is omitted in order to avoid repetition.

FIGS. 3A to 3E are schematic diagrams each illustrating a process of the resist patterning method according to the present embodiment. FIGS. 4A, 4B, and 4C respectively show concentration distribution in the resist layer 10 after the patterned exposure L1, concentration distribution in the resist layer 10 after a first flood exposure L2a, and concentration distribution in the resist layer 10 before and after a second flood exposure L2b.

First, the resist layer 10 is formed on the substrate S as illustrated in FIG. 3A. The resist layer 10 contains the base resin R, the sensitizer precursor Pp, the acid generator PAG, and the base generator PBG.

Next, the patterned exposure L1 is performed on the resist layer 10 as illustrated in FIG. 3B. The regions 10a of the resist layer 10 are irradiated with the beam for the patterned exposure L1, but the regions 10b of the resist layer 10 are not irradiated with the beam for the patterned exposure L1. As a result of the regions 10a of the resist layer 10 being irradiated with the beam through the patterned exposure L1, the sensitizer Ps is produced from the sensitizer precursor Pp in the regions 10a. FIG. 4A illustrates concentration distribution of the sensitizer Ps.

Then, the first flood exposure L2a is performed on the resist layer 10 as illustrated in FIG. 3C. As a result of the entire resist layer 10 being irradiated with a beam through the first flood exposure L2a, the acid Ac is produced from the acid generator PAG with use of the sensitizer Ps as illustrated in FIG. 4B. In the case where the production of the acid Ac is continued until the acid generator PAG has been completely consumed, the acid Ac is no longer produced thereafter, and therefore the acid exhibits a peak concentration that is substantially constant over the entirety of each region 10a. Eventually, the concentration distribution of the acid Ac exhibits very sharp changes at boundaries between the regions 10a and the regions 10b.

Then, the second flood exposure L2b is performed on the resist layer 10 as illustrated in FIG. 3D. As a result of the entire resist layer 10 being irradiated with a beam through the second flood exposure L2b, the base Ba is produced from the base generator PBG.

The following describes production of the base Ba from the base generator PBG with reference to FIG. 4C. Before the second flood exposure L2b is performed, the base generator PBG is distributed in the resist layer 10 substantially uniformly as indicated by t0 in FIG. 4C.

Once the second flood exposure L2b is started, the base generator PBG in the regions 10b is reduced as the base Ba is produced from the base generator PBG as indicated by t1 in FIG. 4C. The base Ba is produced from the base generator PBG also in the regions 10a. However, the base Ba produced in the regions 10a is neutralized with the acid Ac, and thus the concentration of the acid Ac therein is reduced.

As the second flood exposure L2b is further continued, the base generator PBG in the regions 10b is further reduced as indicated by t2 in FIG. 4C. Accordingly, the concentration of the base Ba produced from the base generator PBG increases. The second flood exposure L2b is for example continued until the base generator PBG in the regions 10b has been consumed completely.

The base Ba produced from the base generator PBG in the regions 10a reacts with the acid Ac, and thus the concentration of the acid Ac in the regions 10a is reduced. The peak concentration of the acid Ac and the peak concentration of the base Ba are each substantially constant. The concentration of the acid Ac and the concentration of the base Ba exhibit very sharp changes at boundaries between the regions 10a and the regions 10b. Accordingly, a very large chemical gradient magnitude is obtained after the PEB. The LWR due to photon shot noise is inversely proportional to the chemical gradient magnitude. Therefore, the LWR due to photon shot noise can be significantly reduced.

Then, the resist layer 10 is developed as illustrated in FIG. 3E. As a result of the developing, the regions 10a in which the acid Ac has been produced are removed. Through the above, the resist layer 10 having a pattern according to a pattern shape of the patterned exposure L1 can be formed.

In the description given above with reference to FIGS. 4A to 4C, the second flood exposure L2b is continued until the base generator PBG in the regions 10b has been consumed completely. However, the present invention is not limited to such a configuration. The second flood exposure L2b may not be continued until the base generator PBG in the regions 10b has been consumed completely.

Furthermore, in the description given above with reference to FIGS. 3A to 3E and 4A to 4C, a reaction that produces the base Ba from the base generator PBG is not promoted by the first flood exposure L2a but is promoted by the second flood exposure L2b. This reaction is for example promoted under the following conditions.

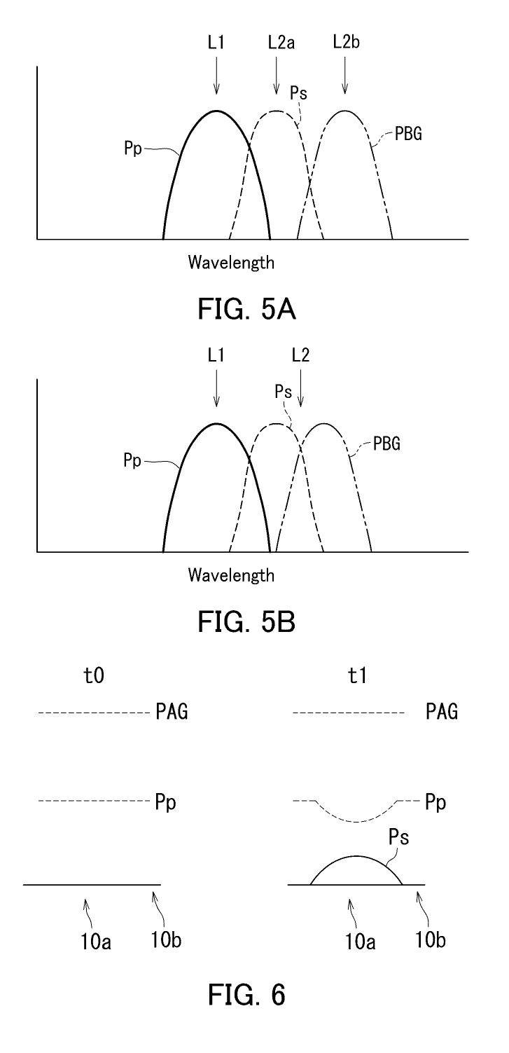

FIG. 5A shows schematic absorption wavelength spectra of the sensitizer precursor Pp, the sensitizer Ps, and the base generator PBG. The sensitizer Ps exhibits longer absorption wavelengths than the sensitizer precursor Pp. The base generator PBG exhibits longer absorption wavelengths than the sensitizer Ps. In such a configuration, the patterned exposure L1 involving irradiation with a beam having a relatively short wavelength causes production of the sensitizer Ps from the sensitizer precursor Pp. Furthermore, the first flood exposure L2a involving irradiation with a beam having a longer wavelength than the beam for the patterned exposure L1 causes production of the acid Ac from the acid generator PAG with use of the sensitizer Ps. Furthermore, the second flood exposure L2b involving irradiation with a beam having a longer wavelength than the beam for the first flood exposure L2a causes production of the base Ba from the base generator PBG.

The schematic absorption wavelength spectra in the embodiment in which the flood exposure is performed twice has been described with reference to FIG. 5A. However, the flood exposure may be performed three or more times. Alternatively, the flood exposure may be performed once as described with reference to FIGS. 1A to 1D and 2A to 2B.

FIG. 5B shows schematic absorption wavelength spectra of the sensitizer precursor Pp, the sensitizer Ps, and the base generator PBG. The acid Ac can be produced from the acid generator PAG with use of the sensitizer Ps, and the base Ba can be produced from the base generator PBG by performing the flood exposure L2 once as described with reference to FIGS. 1A to 1D and 2A to 2B when the absorption wavelength spectrum of the sensitizer Ps overlaps the absorption wavelength spectrum of the base generator PBG such that the absorption wavelength spectra exhibit a relatively high absorptivity at a specific wavelength as illustrated in FIG. 5B.

The sensitizer precursor Pp may be of acetal type or alcohol type. Alternatively, the sensitizer precursor Pp may be a mixture of an acetal-type sensitizer precursor and an alcohol-type sensitizer precursor. In a configuration in which the sensitizer precursor Pp is of acetal type, for example, the acid Ac produced from the acid generator PAG functions as a catalyst to promote production of the sensitizer Ps from the sensitizer precursor Pp. Alternatively, in a configuration in which the sensitizer precursor Pp is of alcohol type, the resist layer 10 contains a radical generating component, and the sensitizer Ps is produced from the sensitizer precursor Pp with use of a radical that is produced.

In the description given above with reference to FIGS. 3A to 5B, the base Ba is produced from the base generator PBG through the second flood exposure L2b. However, the present invention is not limited to such a configuration. The base Ba may be produced from the base generator PBG also through the patterned exposure L1 and/or the first flood exposure L2a as well as through the second flood exposure L2b. In the description given above with reference to FIGS. 3A to 5B, the first flood exposure L2a and the second flood exposure L2b are performed as the flood exposure. However, the present invention is not limited to such a configuration. A third flood exposure for causing production of the acid Ac from the acid generator PAG with use of the sensitizer Ps may be performed after the second flood exposure L2b.

As mentioned above, the sensitizer Ps may be produced directly from the sensitizer precursor Pp through the patterned exposure L1. For example, the sensitizer Ps having different absorption wavelengths or absorption coefficient may be produced through structural transformation of the sensitizer precursor Pp that is excited or ionized through the patterned exposure L1. The structural transformation is for example conjugation length change, decomposition, or cis-trans isomerization. Alternatively, the sensitizer Ps may be produced through a reaction between the sensitizer precursor Pp and an electron generated from a substance contained in the resist layer 10 that is ionized through the patterned exposure L1.

Alternatively, through the patterned exposure L1, the sensitizer Ps may be produced from the sensitizer precursor Pp through a reaction between the sensitizer precursor Pp and the acid Ac produced from the acid generator PAG.

The following describes a resist patterning method and a resist material according to an embodiment of the present invention in which the sensitizer Ps is produced directly from the sensitizer precursor Pp through the patterned exposure L1 with reference to FIGS. 1A to 1D, 2A to 2B, and 6.

FIGS. 1A to 1D are schematic diagrams each illustrating a process of the resist patterning method according to the present embodiment. FIGS. 2A and 2B are schematic diagrams respectively illustrating concentration distribution in the resist layer after the patterned exposure L1 and concentration distribution in the resist layer after the flood exposure L2. FIG. 6 is a schematic diagram illustrating concentration distribution in the resist layer 10 before and after the patterned exposure L1.

First, the resist layer 10 is formed on the substrate S as illustrated in FIG. 1A. The resist layer 10 contains the base resin R, the sensitizer precursor Pp, the acid generator PAG, and the base generator PBG. The base generator PBG is for example hexylammonium 2-(3-benzoylphenyl) propionate.

Next, the patterned exposure L1 is performed on the resist layer 10 as illustrated in FIG. 1B. The regions 10a of the resist layer 10 are irradiated with the beam for the patterned exposure L1, but the regions 10b of the resist layer 10 are not irradiated with the beam for the patterned exposure L1. Accordingly, the sensitizer Ps is produced in the regions 10a as illustrated in FIG. 2A. FIG. 2A illustrates concentration distribution of the sensitizer Ps after the patterned exposure L1.

In the present embodiment, the sensitizer Ps is produced from the sensitizer precursor Pp through the patterned exposure L1. Before the patterned exposure L1 is performed, the acid generator PAG and the sensitizer precursor Pp each have a concentration that is substantially constant throughout the resist layer 10 regardless of location as indicated by t0 in FIG. 6.

Once the patterned exposure L1 is started, the sensitizer Ps is produced from the sensitizer precursor Pp in the regions 10a as indicated by t1 in FIG. 6. The sensitizer Ps has a concentration distribution that is substantially similar to an intensity distribution of the beam for the patterned exposure L1. Note that the concentration of the acid generator PAG in the resist layer does not change at this stage. The sensitizer Ps may for example be produced through cis-trans transformation of the sensitizer precursor Pp as a result of the patterned exposure L1. In this case, the cis-trans transformation is preferably one-way isomerization, which is a reaction that occurs in one direction.

Then, the flood exposure L2 is performed on the resist layer 10 as illustrated in FIG. 1C. The flood exposure L2 imparts energy to the entire resist layer 10. As a result of the imparted energy, the acid Ac is produced from the acid generator PAG in the regions 10a, and the base Ba is produced from the base generator PBG in the entire resist layer 10 as illustrated in FIG. 2B. Even though the regions 10b, in which the sensitizer Ps is not produced, are irradiated with the beam for the flood exposure L2, neither the acid generator PAG nor the sensitizer precursor Pp in the regions 10b substantially reacts.

Then, the resist layer 10 is developed as illustrated in FIG. 1D. As a result of the developing, the regions 10a in which the acid Ac has been produced are removed. Through the above, the resist layer 10 having a pattern according to a pattern shape of the patterned exposure L1 can be formed.

In the description given above with reference to FIGS. 1A to 1D, 2A to 2B, and 6, the sensitizer Ps is produced directly from the sensitizer precursor Pp through the patterned exposure L1. However, the present invention is not limited to such a configuration. The sensitizer Ps may be produced from the sensitizer precursor Pp through a reaction between the sensitizer precursor Pp and the acid Ac produced through the patterned exposure L1.

The following describes a resist patterning method and a resist material according to an embodiment of the present invention with reference to FIGS. 3A to 3E, 4A to 4C, 7, and 8. The sensitizer precursor Pp in the resist patterning method according to the present embodiment is of acetal type. In the present embodiment, the acid Ac is produced from the acid generator PAG through the patterned exposure L1, and the produced acid Ac promotes a reaction of the sensitizer precursor Pp to produce the sensitizer Ps.

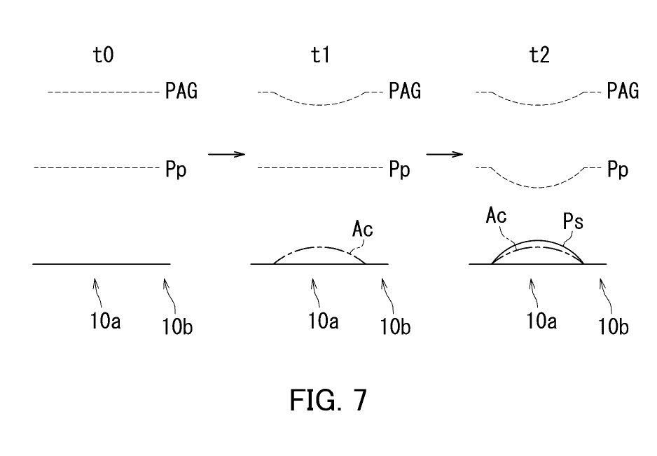

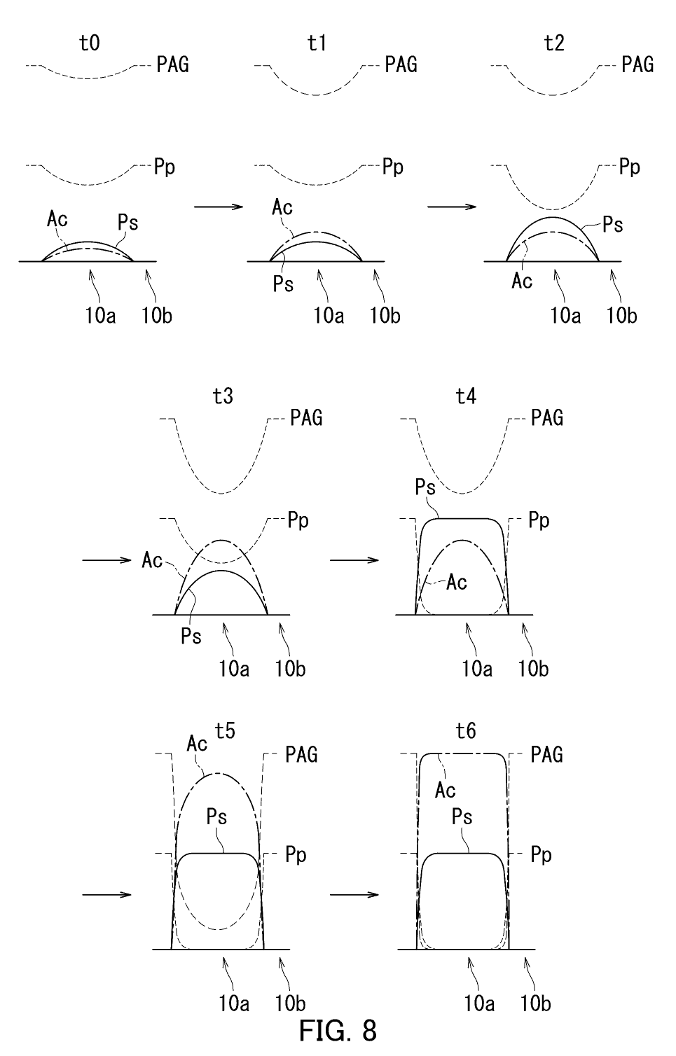

FIGS. 3A to 3E are schematic diagrams each illustrating a process of the resist patterning method according to the present embodiment. FIG. 7 illustrates concentration distribution in the resist layer 10 before and after the patterned exposure L1. FIG. 8 illustrates concentration distribution in the resist layer 10 before and after the first flood exposure L2a.

First, the resist layer 10 is formed on the substrate S as illustrated in FIG. 3A. The resist layer 10 contains the base resin R, the sensitizer precursor Pp, the acid generator PAG, and the base generator PBG.

Next, the patterned exposure L1 is performed on the resist layer 10 as illustrated in FIG. 3B. The regions 10a of the resist layer 10 are irradiated with the beam for the patterned exposure L1, but the regions 10b of the resist layer 10 are not irradiated with the beam for the patterned exposure L1.

Before the patterned exposure L1 is performed, the acid generator PAG and the sensitizer precursor Pp each have a concentration that is substantially constant throughout the resist layer 10 regardless of location as indicated by t0 in FIG. 7. Once the patterned exposure L1 is started, the acid Ac is produced from the acid generator PAG in the regions 10a as indicated by t1 in FIG. 7. As a result, the concentration of the acid Ac in the regions 10a increases, whereas the concentration of the acid generator PAG in the regions 10a decreases to be lower than the concentration of the acid generator PAG in the regions 10b. The acid Ac has a concentration distribution that is substantially similar to the intensity distribution of the beam for the patterned exposure L1.

The acid Ac produced in the region 10a functions as a catalyst to promote production of the sensitizer Ps from the sensitizer precursor Pp as indicated by t2 in FIG. 7. As a result, the concentration of the sensitizer Ps in the regions 10a increases, whereas the concentration of the sensitizer precursor Pp in the regions 10a decreases to be lower than the concentration of the sensitizer precursor Pp in the regions 10b.

Next, the first flood exposure L2a is performed on the resist layer 10 as illustrated in FIG. 3C. Before irradiation with the beam for the first flood exposure L2a, the concentration of the acid generator PAG and the concentration of the sensitizer precursor Pp in the regions 10a are respectively lower than the concentration of the acid generator PAG and the concentration of the sensitizer precursor Pp in the regions 10b as indicated by t0 in FIG. 8.

Once the first flood exposure L2a is started, the acid Ac is produced from the acid generator PAG with use of the sensitizer Ps in the regions 10a as indicated by t1 in FIG. 8. As a result, the concentration of the acid Ac in the regions 10a increases, whereas the concentration of the acid generator PAG in the region 10a further decreases.

The acid Ac produced in the regions 10a functions as a catalyst to promote production of the sensitizer Ps from the sensitizer precursor Pp as indicated by t2 in FIG. 8. As a result, the concentration of the sensitizer Ps in the regions 10a increases, whereas the concentration of the sensitizer precursor Pp in the regions 10a further decreases. The production of the sensitizer Ps from the sensitizer precursor Pp is a reaction catalyzed by the acid Ac. That is, the production of the sensitizer Ps from the sensitizer precursor Pp proceeds with use of the acid Ac but does not consume the acid Ac.

As the first flood exposure L2a is further continued, the acid Ac is further produced from the acid generator PAG with use of the increased sensitizer Ps in the regions 10a as indicated by t3 in FIG. 8. As a result, the concentration of the acid Ac increases and the concentration of the acid generator PAG further decreases in the regions 10a.

The acid Ac produced in the regions 10a functions as a catalyst to promote production of the sensitizer Ps from the sensitizer precursor Pp as indicated by t4 in FIG. 8. As a result, the concentration of the sensitizer precursor Pp in the regions 10a further decreases. The sensitizer precursor Pp in the regions 10a has been converted to the sensitizer Ps substantially completely by this stage. Therefore, unlike the distribution of the acid Ac produced through the patterned exposure L1, the sensitizer Ps has a substantially constant peak concentration in the concentration distribution of the sensitizer Ps in the regions 10a.

As the first flood exposure L2a is further continued, the acid Ac is further produced from the acid generator PAG with use of the increased sensitizer Ps in the regions 10a as indicated by t5 in FIG. 8. As a result, the concentration of the acid Ac further increases and the concentration of the acid generator PAG further decreases in the regions 10a. Changing from the concentration distribution of the acid Ac produced through the patterned exposure L1, the concentration distribution of the acid Ac after the first flood exposure L2a has a substantially constant peak concentration at an approximate center of each region 10a.

Since little sensitizer precursor Pp is present in the regions 10a at this stage, production of the sensitizer Ps from the sensitizer precursor Pp catalyzed by the acid Ac hardly occurs. Accordingly, as indicated by t6 in FIG. 8, the concentration of the acid Ac increases and the concentration of the acid generator PAG further decreases in the regions 10a. Once the acid generator PAG in the regions 10a has been converted to the acid Ac substantially completely, the acid Ac in the regions 10a exhibits a substantially constant peak concentration. The first flood exposure L2a is continued until the acid Ac has a substantially constant peak concentration throughout the regions 10a on which, of the resist layer 10, the patterned exposure L1 and the first flood exposure L2a have been performed. Accordingly, the concentration of the acid Ac exhibits sharp changes at boundaries between the regions 10a and the regions 10b.

Then, the second flood exposure L2b is performed on the resist layer 10 as illustrated in FIG. 3D. As a result of the entire resist layer 10 being irradiated with the beam through the second flood exposure L2b, the base Ba is produced from the base generator PBG as described above with reference to FIG. 4C.

As illustrated in FIG. 4C, the peak concentration of the acid Ac and the peak concentration of the base Ba are each substantially constant. The concentration of the acid Ac and the concentration of the base Ba exhibit very sharp changes at boundaries between the regions 10a and the regions 10b. Accordingly, a very large chemical gradient magnitude is obtained through the reaction after the subsequent PEB. As mentioned above, the LWR is inversely proportional to the chemical gradient magnitude, and likewise the LWR due to photon shot noise is inversely proportional to the chemical gradient magnitude. Therefore, the LWR due to photon shot noise can be significantly reduced.

Then, the resist layer 10 is developed as illustrated in FIG. 3E. As a result of the developing, the regions 10a in which the acid Ac has been produced are removed. Through the above, the resist layer 10 having a pattern according to a pattern shape of the patterned exposure L1 can be formed.

As described above, according to the present embodiment, the trade-off between the sensitivity, the resolution, and the line width roughness (LWR) can be solved, and therefore the sensitivity of the resist layer 10 can be increased while maintaining the pattern resolution. Furthermore, photon shot noise, which has recently been considered a bigger problem than the trade-off, can be significantly improved. As a result, the throughput in the exposure process can be improved, and significant cost reduction for the exposure system can be achieved. Furthermore, since a low-power light source can be used, the lives of consumable parts of the light source device and the exposure device can be extended, and the maintenance cost and the operation cost can be significantly reduced.

In the description given above with reference to FIG. 8, the first flood exposure L2a is continued until the sensitizer precursor Pp and the acid generator PAG in the regions 10a have been consumed completely. However, the present invention is not limited to such a configuration. The first flood exposure L2a does not need to be continued until the sensitizer precursor Pp and the acid generator PAG in the regions 10a have been consumed completely.

In the description given above with reference to FIGS. 3A to 3E, 4A to 4C, 7, and 8, the acid Ac produced from the acid generator PAG through the patterned exposure L1 functions as a catalyst, promoting production of the sensitizer Ps from the sensitizer precursor Pp. This reaction is for example promoted under the following conditions.

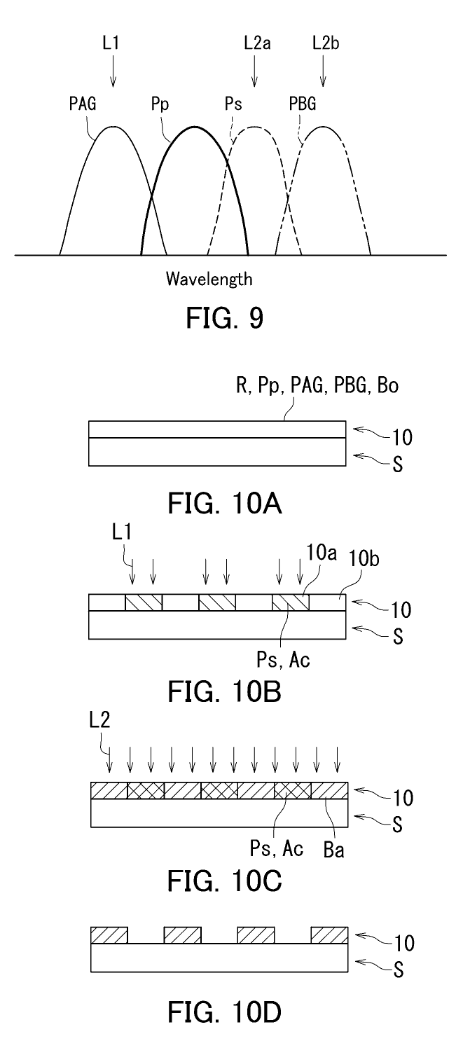

FIG. 9 shows schematic absorption wavelength spectra of the acid generator PAG, the sensitizer precursor Pp, the sensitizer Ps, and the base generator PBG. Typically, the sensitizer precursor Pp exhibits longer absorption wavelengths than the acid generator PAG. The sensitizer Ps exhibits longer absorption wavelengths than the sensitizer precursor Pp. The base generator PBG exhibits longer absorption wavelengths than the sensitizer Ps.

In such a configuration, the patterned exposure L1 involving irradiation with a beam having a relatively short wavelength causes production of the acid Ac from the acid generator PAG, and the acid Ac functions as a catalyst to promote production of the sensitizer Ps from the sensitizer precursor Pp. Furthermore, the first flood exposure L2a involving irradiation with a beam having a longer wavelength than the beam for the patterned exposure L1 causes production of the acid Ac from the acid generator PAG with use of the sensitizer Ps. Furthermore, the second flood exposure L2b involving irradiation with a beam having a longer wavelength than the beam for the first flood exposure L2a causes production of the base Ba from the base generator PBG. Note that the description given above with reference to FIG. 5B also applies to FIG. 9. That is, both the acid Ac and the base Ba may be produced by performing the flood exposure L2 once.

In the description given above, the resist layer 10 contains the base generator PBG but contains no base before the patterned exposure L1 is performed. However, the present invention is not limited to such a configuration. The resist layer 10 may contain a base before the patterned exposure L1 is performed.

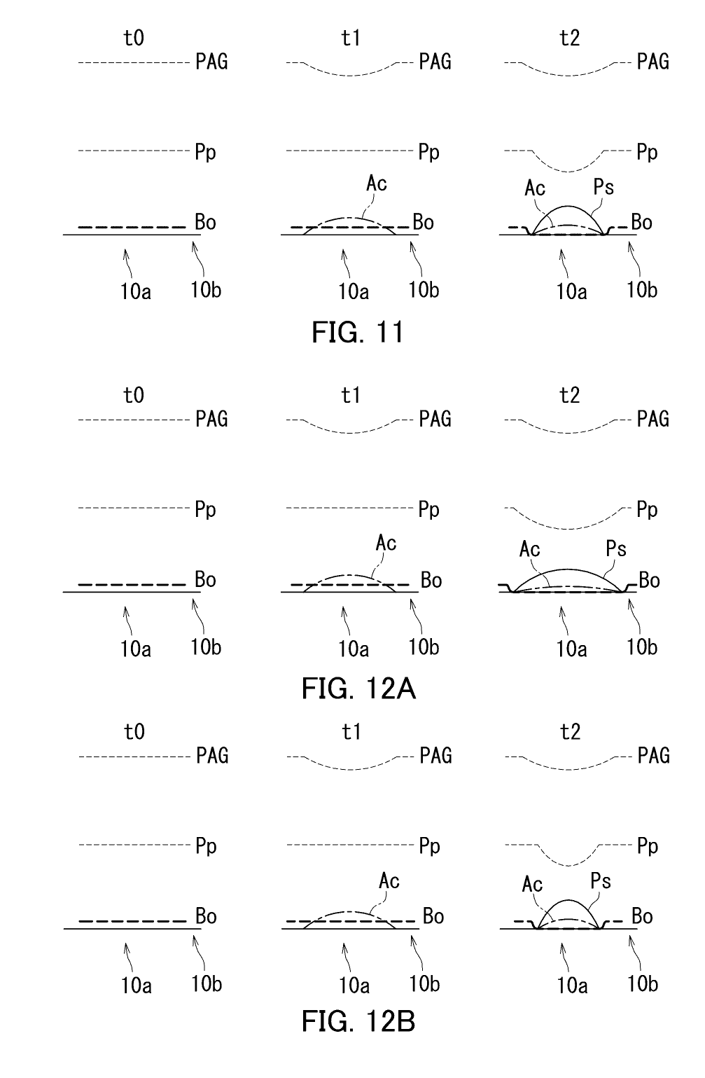

The following describes a resist patterning method and a resist material according to an embodiment of the present invention with reference to FIGS. 10A to 10D and 11. The resist patterning method and the resist material according to the present embodiment are similar to the resist patterning method and the resist material described with reference to FIGS. 1A to 1D and 2A to 2B except that the resist layer 10 has a base component Bo before the patterned exposure L1 is performed. Accordingly, redundant description thereof is omitted in order to avoid repetition. The resist layer 10 is basic because of the base component Bo. Accordingly, decomposition of the sensitizer precursor Pp can be inhibited, and a minor concentration of acid can be avoided, which is produced in the regions 10b by out-of-band light when EUV is used for the patterned exposure L1.

FIGS. 10A to 10D are schematic diagrams each illustrating a process of the resist patterning method according to the present embodiment. FIG. 11 illustrates concentration distribution in the resist layer 10 before and after the patterned exposure L1.

First, the resist layer 10 is formed on the substrate S as illustrated in FIG. 10A. The resist layer 10 contains the base resin R, the sensitizer precursor Pp, the acid generator PAG, the base generator PBG, and the base component Bo. In the resist layer 10, for example, the sensitizer precursor Pp is contained in an amount of at least 0.1 parts by mass and no greater than 40 parts by mass, the acid generator PAG is contained in an amount of at least 0.1 parts by mass and no greater than 40 parts by mass, and the base generator PBG is contained in an amount of greater than 0 parts by mass and no greater than 40 parts by mass, and the base component Bo is contained in an amount of no greater than 10 parts by mass, relative to 100 parts by mass of the base resin R.

An amine compound such as trioctylamine is for example used as the base component (basic compound) Bo. The base component Bo may be mixed in the base resin R. Alternatively, the base component Bo may be bound to another component of the resist layer 10. For example, the base component Bo is bound to the base resin R. The base component Bo preferably has a low diffusion coefficient.

Next, the patterned exposure L1 is performed on the resist layer 10 as illustrated in FIG. 10B. The regions 10a of the resist layer 10 are irradiated with the beam for the patterned exposure L1, but the regions 10b of the resist layer 10 are not irradiated with the beam for the patterned exposure L1.

As indicated by t0 in FIG. 11, the acid generator PAG, the sensitizer precursor Pp, and the base component Bo each have a concentration that is substantially constant throughout the resist layer 10 regardless of location before the patterned exposure L1 is performed. The concentration of the base component Bo may be relatively low compared to the concentrations of the acid generator PAG and the sensitizer precursor Pp.

Once the patterned exposure L1 is started, the acid Ac is produced from the acid generator PAG in the regions 10a as indicated by t1 in FIG. 11. As a result, the concentration of the acid Ac in the regions 10a increases, whereas the concentration of the acid generator PAG in the regions 10a decreases to be lower than the concentration of the acid generator PAG in the regions 10b. The acid Ac has a concentration distribution that is substantially similar to the intensity distribution of the beam for the patterned exposure L1.

Since the resist layer 10 according to the present embodiment contains the base component Bo, the acid Ac is neutralized through a reaction with the base component Bo. As a result, as indicated by t2 in FIG. 11, the concentration distribution of the acid Ac is sharper than the concentration distribution obtained when the resist layer 10 contains no base component Bo.

The acid Ac produced in the regions 10a functions as a catalyst to promote production of the sensitizer Ps from the sensitizer precursor Pp as indicated by t2 in FIG. 11. As a result, the concentration of the sensitizer Ps in the regions 10a decreases to be lower than the concentration of the sensitizer precursor Pp in the regions 10b. Since the concentration distribution of the acid Ac is sharper than the concentration distribution obtained when the resist layer 10 contains no base component Bo, the concentration distribution of the sensitizer Ps produced with use of the acid Ac is also sharp.

Next, the flood exposure L2 is performed on the resist layer 10 as illustrated in FIG. 10C. Since the concentration distribution of the sensitizer Ps produced through the patterned exposure L1 is sharp, the concentration distribution of the acid Ac produced from the acid generator PAG with use of the sensitizer Ps can be sharp.

Then, the resist layer 10 is developed as illustrated in FIG. 10D. As described above, adding in advance a small amount of the base component Bo to the resist layer 10 enables an improvement in contrast and resolution, inhibition of production of a small amount of acid as a result of the regions 10b being irradiated with stray light or out-of-band light, and an improvement in resist performance.

As mentioned above, the sensitizer Ps may be produced from the sensitizer precursor Pp through a reaction between the sensitizer precursor Pp and the acid Ac produced from the acid generator PAG through the patterned exposure L1. In such a configuration, a process 1 may be performed in which the sensitizer Ps is produced through a reaction between the sensitizer precursor Pp and the acid Ac as a result of the patterned exposure L1, and subsequently a process 2 may be performed in which the excited sensitizer Ps reacts with the acid generator PAG as a result of the flood exposure L2.

In the process 1, the sensitizer Ps is produced through a reaction between the sensitizer precursor Pp and the acid Ac as a result of the patterned exposure L1. Typically, the acid Ac diffuses in the resist layer and reacts with the sensitizer precursor Pp that is present around the diffusing acid Ac, such that the sensitizer Ps is produced from the acid Ac and the sensitizer precursor Pp. That is, the process 1 proceeds through diffusion of the acid Ac. The diffusion length varies greatly depending on base concentration, acid molecule size, temperature, resist glass transition point Tg, and the like. Generally, the diffusion length of the acid Ac increases with increase in temperature. For example, the diffusion length of the acid Ac is relatively long at a temperature higher than the glass transition point Tg of the base resin. As described above, the process 1 is a reaction associated with thermal diffusion of the acid Ac. That is, the reaction between the acid Ac and the sensitizer precursor Pp can occur even at a point distant from a point at which the acid Ac has been produced.

In the process 2, typically, the exited sensitizer Ps reacts with the acid generator PAG to produce the acid Ac. That is, the process 2 is a photochemical reaction that causes transfer such as electron transfer or energy transfer. This reaction is three-dimensional and highly isotropic, and occurs at a relatively short distance from the excited sensitizer Ps.

Hereinafter, roughness and photon shot noise in the process 1 and the process 2 will be discussed. In a configuration in which the reaction is caused to proceed using a small amount of photons, in particular, roughness due to photon shot noise may be noticeable. In order to reduce roughness due to photon shot noise, the reaction distance is preferably short both in the process 1 and the process 2. The reaction distance varies more in the process 1, which is associated with the thermal diffusion, than in the process 2. In a configuration in which the concentration of the acid Ac is relatively low, in particular, the reaction in the process 1 tends to result in roughness due to photon shot noise associated with the diffusion. In order to reduce roughness due to photon shot noise, therefore, the diffusion length of the acid Ac is preferably adjusted to be relatively short by reducing the temperature, so long as the reaction that produces the sensitizer Ps from the acid Ac and the sensitizer precursor Pp proceeds efficiently in the process 1. Preferably, the patterned exposure L1 is for example performed in view of temperature dependency of the diffusion of the acid Ac, the temperature dependency of the reaction that produces the sensitizer Ps from the acid Ac and the sensitizer precursor Pp, and the like.

In the process 2, it is preferable that the excited sensitizer Ps and the acid generator PAG are selected so that the acid Ac is produced efficiently through the three-dimensional and highly isotropic electron transfer or energy transfer from the exited sensitizer Ps to the acid generator PAG and that the concentration of the acid generator PAG is high. Furthermore, it is effective for reducing roughness and photon shot noise-induced roughness that the proportion of the process 2 is larger than the proportion of the process 1. As described above, it is preferable that in the patterned exposure L1 and the flood exposure L2, the diffusion distance of the acid Ac in the reaction between the acid Ac and the sensitizer precursor Pp is short, and the reaction distance of the electron transfer or the energy transfer from the exited sensitizer Ps to the acid generator PAG is short. Furthermore, it is preferable that contribution of the reaction that produces the acid Ac using the three-dimensional and highly isotropic electron transfer or energy transfer is greater than contribution of the reaction depending on random diffusion paths of the acid Ac and the like. Thus, roughness due to photon shot noise in a resultant resist pattern can be reduced.

As mentioned above, in a configuration in which the sensitizer Ps is produced from the sensitizer precursor Pp through a reaction between the sensitizer precursor Pp and the acid Ac produced from the acid generator PAG through the patterned exposure L1, the sensitizer precursor Pp preferably not only functions as a reactant for producing the sensitizer Ps but also has sensitizing action on the reaction that produces the acid Ac from the acid generator PAG. In this case, the sensitizer precursor Pp contributes to an improvement in sensitivity and contrast. Examples of such a sensitizer precursor Pp include acetals, ketals, and hemiacetals (semiketals). A more specific example of the sensitizer precursor Pp is dimethoxybis(4-methoxyphenyl)methane (DOBzMM), which is a dimethoxy benzhydrol derivative. The aromatic moiety of DOBzMM has a benzene ring structure. The sensitizer precursor Pp is for example an acetal, a ketal, or a hemiacetal (semiketal) having a structure of a heteroatom-containing aromatic molecule such as thioxanthone or polycyclic aromatic hydrocarbons including naphthalene and anthracene. Preferably, in the patterned exposure L1, the sensitizer precursor Pp has either or both of sensitizing action on the reaction that produces the sensitizer Ps from the sensitizer precursor Pp and sensitizing action on the reaction that produces the acid Ac from the acid generator PAG.

In the description given above with reference to FIGS. 10A to 10D and 11, the diffusion coefficient of the acid Ac and the diffusion coefficient of the base component Bo are substantially equal to one another, and therefore both of diffusion of the acid Ac and diffusion of the base component Bo in the regions 10a irradiated with the beam for the patterned exposure L1 are not described. However, the present invention is not limited to such a configuration. The diffusion coefficient of the acid Ac may be higher than the diffusion coefficient of the base component Bo. Alternatively, the diffusion coefficient of the acid Ac may be lower than the diffusion coefficient of the base component Bo.

The following describes, with reference to FIG. 12A, changes in concentration distributions in the resist layer when the patterned exposure L1 is performed in a configuration in which the diffusion coefficient of the acid Ac is higher than the diffusion coefficient of the base component Bo.

Once the patterned exposure L1 is started, the acid Ac is produced from the acid generator PAG in the regions 10a as indicated by t1 in FIG. 12A. As a result, the concentration of the acid Ac in the regions 10a increases, whereas the concentration of the acid generator PAG in the regions 10a decreases to be lower than the concentration of the acid generator PAG in the regions 10b. The acid Ac has a concentration distribution that is substantially similar to the intensity distribution of the beam for the patterned exposure L1.

Since the resist layer 10 contains the base component Bo, the acid Ac is neutralized through a reaction with the base component Bo. Since the diffusion coefficient of the acid Ac is higher than the diffusion coefficient of the base component Bo in the present configuration, the acid Ac diffuses to have a widened concentration distribution and a lowered peak as indicated by t2 in FIG. 12A. The acid Ac produced in the regions 10a functions as a catalyst to promote production of the sensitizer Ps from the sensitizer precursor Pp as indicated by t2 in FIG. 12A. As a result, the concentration of the sensitizer precursor Pp in the regions 10a decreases to be lower than the concentration of the sensitizer precursor Pp in the regions 10b. As described above, the concentration distribution of the acid Ac is relatively wide. Accordingly, the concentration distribution of the sensitizer Ps produced with use of the acid Ac is widened. Thus, the sensitizer Ps can be produced to have a concentration distribution wider than each region irradiated with the beam for the patterned exposure L1.

As described above with reference to FIG. 12A, the diffusion coefficient of the acid Ac may be higher than the diffusion coefficient of the base component Bo, but the diffusion coefficient of the acid Ac may be lower than the diffusion coefficient of the base component Bo.

The following describes, with reference to FIG. 12B, changes in concentration distributions in the resist layer when the patterned exposure L1 is performed in a configuration in which the diffusion coefficient of the acid Ac is lower than the diffusion coefficient of the base component Bo.

Once the patterned exposure L1 is started, the acid Ac is produced from the acid generator PAG in the regions 10a as indicated by t1 in FIG. 12B. As a result, the concentration of the acid Ac in the regions 10a increases, whereas the concentration of the acid generator PAG in the regions 10a decreases to be lower than the concentration of the acid generator PAG in the regions 10b. The acid Ac has a concentration distribution that is substantially similar to the intensity distribution of the beam for the patterned exposure L1.

Since the resist layer 10 contains the base component Bo, the acid Ac is neutralized through a reaction with the base component Bo. Since the diffusion coefficient of the acid Ac is lower than the diffusion coefficient of the base component Bo in the present configuration, the base component Bo diffuses, and the acid Ac has a relatively narrow concentration distribution as indicated by t2 in FIG. 12B. The acid Ac produced in the regions 10a functions as a catalyst to promote production of the sensitizer Ps from the sensitizer precursor Pp as indicated by t2 in FIG. 12B. As a result, the concentration of the sensitizer precursor Pp in the regions 10a decreases to be lower than the concentration of the sensitizer precursor Pp in the regions 10b. As described above, the concentration distribution of the acid Ac is relatively narrow. Accordingly, the concentration distribution of the sensitizer Ps produced with use of the acid Ac is narrowed. Thus, the sensitizer Ps can be produced to have a concentration distribution narrower than each region irradiated with the beam for the patterned exposure L1.

In the description given above with reference to FIGS. 10A to 12B, the product of the neutralization reaction between the acid Ac and the base component Bo is not involved in the processes 1 and 2. However, the present invention is not limited to such a configuration. The same acid generator PAG as the acid generator PAG contained in the resist layer 10 may be newly produced through the neutralization reaction between the acid Ac and the base component Bo.

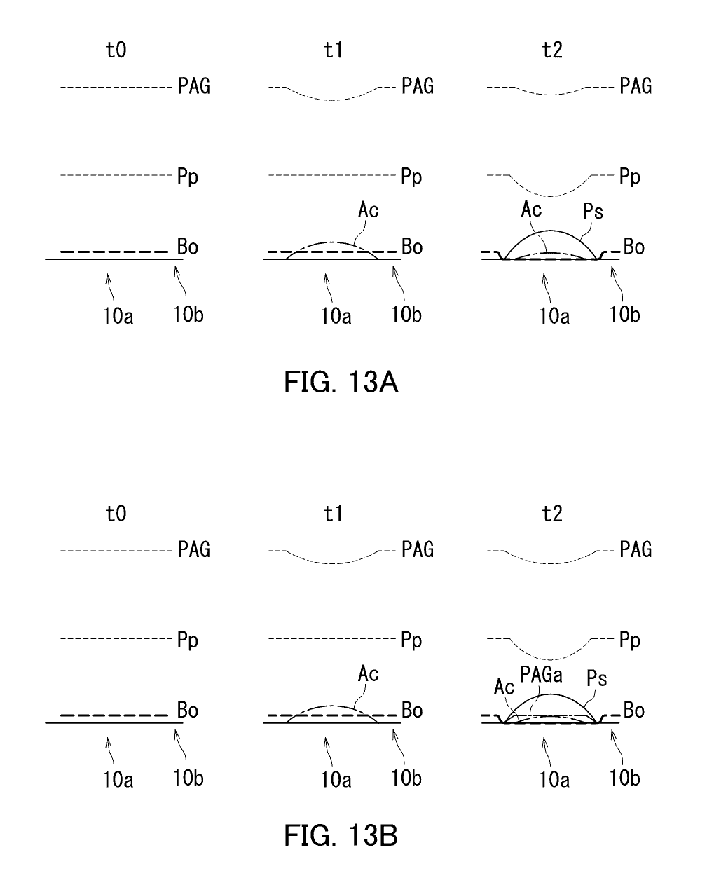

The following describes, with reference to FIG. 13A, changes in concentration distributions in the resist layer when the patterned exposure L1 is performed in a configuration in which the acid generator PAG is newly produced through the neutralization reaction between the acid Ac and the base component Bo. The acid generator PAG, the acid Ac, and the base component Bo in the resist layer are for example AX, HX, and AY, respectively.

Once the patterned exposure L1 is started, the acid Ac (HX) is produced from the acid generator PAG (AX) in the regions 10a as indicated by t1 in FIG. 13A. As a result, the concentration of the acid Ac (HX) in the regions 10a increases, whereas the concentration of the acid generator PAG (AX) in the regions 10a decreases to be lower than the concentration of the acid generator PAG (AX) in the regions 10b. The acid Ac (HX) has a concentration distribution that is substantially similar to the intensity distribution of the beam for the patterned exposure L1.

Since the resist layer 10 contains the base component Bo (AY), the acid Ac (HX) is neutralized through a reaction with the base component Bo (AY). Since the acid generator PAG (AX) is newly produced through the neutralization reaction between the acid Ac (HX) and the base component Bo (AY) in the present configuration, the concentration of the acid generator PAG (AX) in the regions 10a is recovered as indicated by t2 in FIG. 13A. The acid Ac (HX) produced in the regions 10a functions as a catalyst to promote production of the sensitizer Ps from the sensitizer precursor Pp as indicated by t2 in FIG. 13A. As a result, the concentration of the sensitizer precursor Pp in the regions 10a decreases to be lower than the concentration of the sensitizer precursor Pp in the regions 10b.

As described above, as a result of the acid generator PAG being newly produced through the neutralization reaction between the acid Ac and the base component Bo, the concentration of the acid generator PAG does not change or changes by a reduced amount through the patterned exposure L1. Thus, the concentration of the acid generator PAG after the patterned exposure L1 can be maintained high, and the concentration of the acid that is produced through the flood exposure L2 can be increased.

Note that a compound (for example, a compound (HY)) may be produced in addition to the acid generator PAG (AX) through the neutralization reaction between the acid Ac (HX) and the base component Bo (AY). However, such a compound does not cause an acid-catalyzed reaction, and therefore does not contribute to production of the sensitizer Ps from the sensitizer precursor Pp or to a chemically amplified resist reaction.

In the description given above with reference to FIG. 13A, the acid generator PAG is newly produced through the neutralization reaction between the acid Ac and the base component Bo. However, the present invention is not limited to such a configuration. An acid generator that is different from the acid generator PAG may be produced through the neutralization reaction between the acid Ac and the base component Bo.

The following describes, with reference to FIG. 13B, changes in concentration distributions in the resist layer when the patterned exposure L1 is performed in a configuration in which an acid generator PAGa that is different from the acid generator PAG present in the resist layer is produced through the neutralization reaction between the acid Ac and the base component Bo. The acid Ac, the base component Bo, the acid generator PAG, and the acid generator PAGa are for example HX, BY, AX, and BX, respectively.

Once the patterned exposure L1 is started, the acid Ac (HX) is produced from the acid generator PAG (AX) in the regions 10a as indicated by t1 in FIG. 13B. As a result, the concentration of the acid Ac (HX) in the regions 10a increases, whereas the concentration of the acid generator PAG (AX) in the regions 10a decreases to be lower than the concentration of the acid generator PAG (AX) in the regions 10b. The acid Ac (HX) has a concentration distribution that is substantially similar to the intensity distribution of the beam for the patterned exposure L1.

Since the resist layer 10 contains the base component Bo (BY), the acid Ac (HX) is neutralized through a reaction with the base component Bo (BY). In the present configuration, the acid generator PAGa (BX) that is different from the acid generator PAG (AX) contained in the resist layer 10 is produced through the neutralization reaction between the acid Ac (HX) and the base component Bo (BY) as indicated by t2 in FIG. 13A. The acid Ac (HX) produced in the regions 10a functions as a catalyst to promote production of the sensitizer Ps from the sensitizer precursor Pp as indicated by t2 in FIG. 13B. As a result, the concentration of the sensitizer precursor Pp in the regions 10a decreases to be lower than the concentration of the sensitizer precursor Pp in the regions 10b.

The acid Ac produced in the regions 10a functions as a catalyst to promote production of the sensitizer Ps from the sensitizer precursor Pp as indicated by t2 in FIG. 13B. As a result, the concentration of the sensitizer precursor Pp in the regions 10a decreases to be lower than the concentration of the sensitizer precursor Pp in the regions 10b.

As described above, as a result of the acid generator PAGa being produced through the neutralization reaction between the acid Ac and the base component Bo, a sum of the concentration of the acid generator PAG and the concentration of the acid generator PAGa in the regions 10a after the patterned exposure L1 is substantially equal to or lower by a reduced amount than the concentration of the acid generator PAG before the patterned exposure L1 even though the concentration of the acid generator PAG in the regions 10a is reduced through the patterned exposure L1. Thus, the concentration of the acid generator after the patterned exposure L1 can be maintained high, and the concentration of the acid that is produced through the flood exposure L2 can be increased.

As described with reference to FIGS. 9 to 13B, the resist layer 10 preferably contains the base component Bo. The base component Bo plays in the resist layer 10 a very important role of determining spatial distribution of the acid Ac and spatial distribution of the sensitizer Ps, which are important for resolution and roughness, until the base Ba is produced from the base generator PBG. In order to form a pattern having a desired high resolution and reduced roughness, it is preferable that the concentration of the base component Bo is sufficiently high until the base Ba is produced from the base generator PBG.

Of the base component Bo contained in the resist layer 10, the base component Bo located in the regions 10b, which are not irradiated with the beam for the patterned exposure L1, quenches the acid Ac produced in the regions 10b. Thus, photon shot noise can be reduced efficiently. In contrast, the base component Bo located in the regions 10a quenches the acid Ac produced in the regions 10a. In order to prevent the acid Ac in the regions 10a from being quenched, the base component Bo is preferably decomposed through the patterned exposure L1. Thus, the acid Ac can be prevented from being produced in the regions 10b, and the acid Ac produced in the regions 10a can be prevented from being quenched. It is for example preferable that extreme ultraviolet light, an electron beam, or ArF is used as the beam for the patterned exposure L1, and a photolyzable base is used as the base component Bo.

In order to prevent the acid Ac in the regions 10a from being quenched, the base component Bo is preferably lost to decomposition through a reaction with the sensitizer Ps excited by the irradiation with the beam for the flood exposure L2. In a configuration in which the first flood exposure L2a and the second flood exposure L2b are performed as the flood exposure L2, for example, the base component Bo is preferably lost to decomposition through a reaction between the base component Bo and the sensitizer Ps excited by the irradiation with the beam for the first flood exposure L2a. Thus, the acid Ac can be prevented from being produced in the regions 10b, and the acid Ac produced in the regions 10a can be prevented from being quenched.

Of the base generator PBG contained in the resist layer 10, the base generator PBG located in the regions 10b, which are not irradiated with the beam for the patterned exposure L1, produces the base Ba, and the base Ba quenches the acid Ac even if the acid Ac is produced in the regions 10b. Thus, photon shot noise can be reduced efficiently. In contrast, if the base generator PBG located in the regions 10a, which are irradiated with the beam for the patterned exposure L1, reacts with the excited sensitizer Ps to produce the base Ba, the produced base Ba quenches the acid Ac produced in the regions 10a. It is therefore preferable that the base generator PBG does not react with the sensitizer Ps excited by the irradiation with the beam for the flood exposure L2 or reacts with the excited sensitizer Ps but does not produce the base Ba. Thus, the acid Ac can be prevented from being produced in the regions 10b, and the acid Ac produced in the regions 10a can be prevented from being quenched. It is for example preferable to use light emitted from an LED and having a wavelength of 365 nm as the beam for the flood exposure L2 and use dicyclohexylammonium 2-(3-benzoylphenyl) propionate as the base generator PBG.

In the description given above with reference to FIGS. 10A to 13B, the acid Ac produced from the acid generator PAG through the patterned exposure L1 reacts with the sensitizer precursor Pp to produce the sensitizer Ps, and the resist layer 10 contains the base component Bo before the patterned exposure L1 is performed. However, the present invention is not limited to such a configuration. The resist layer 10 may be configured to produce the sensitizer Ps from the sensitizer precursor Pp with use of a radical produced through the patterned exposure L1, and the resist layer 10 may contain a radical scavenger component Rk before the patterned exposure L1 is performed.

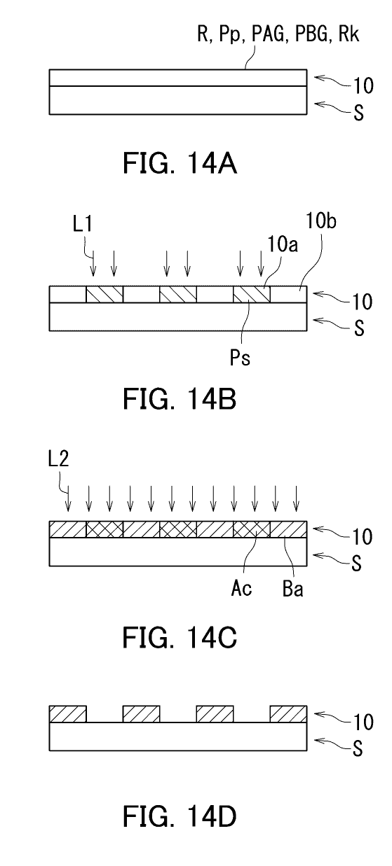

The following describes a resist patterning method and a resist material according to an embodiment of the present invention with reference to FIGS. 14A to 14D. The resist patterning method and the resist material according to the present embodiment are similar to the resist patterning method and the resist material described with reference to FIGS. 1A to 1D and 2A to 2B except that the resist layer 10 contains the radical scavenger component Rk before the patterned exposure L1 is performed. Accordingly, redundant description thereof is omitted in order to avoid repetition. In the present embodiment, the sensitizer precursor Pp in the resist layer 10 is of alcohol type, and the sensitizer Ps is produced from the sensitizer precursor Pp with use of the radical produced through the patterned exposure L1.

FIGS. 14A to 14D are schematic diagrams each illustrating a process of the resist patterning method according to the present embodiment.

First, the resist layer 10 is formed on the substrate S as illustrated in FIG. 14A. The resist layer 10 contains the base resin R, the sensitizer precursor Pp, the acid generator PAG, the base generator PBG, and the radical scavenger component Rk.

A radical scavenger such as hindered phenol or a radical inhibitor is for example used as the radical scavenger component Rk. The radical scavenger component Rk may be mixed in the base resin R. Alternatively, the radical scavenger component Rk may be bound to another component of the resist layer 10. The radical scavenger component Rk is for example bound to the base resin R. In a configuration in which a polyhydroxystyrene resin (PHS resin) is used as the base resin R, the PHS resin can function as the radical scavenger.

Next, the patterned exposure L1 is performed on the resist layer 10 as illustrated in FIG. 14B. The regions 10a of the resist layer 10 are irradiated with the beam for the patterned exposure L1, but the regions 10b of the resist layer 10 are not irradiated with the beam for the patterned exposure L1.

Before the patterned exposure L1 is performed, the acid generator PAG, the sensitizer precursor Pp, and the radical scavenger component Rk each have a concentration that is substantially constant throughout the resist layer 10 regardless of location. The concentration of the radical scavenger component Rk is relatively low compared to the concentrations of the acid generator PAG and the sensitizer precursor Pp.

Once the patterned exposure L1 is started, a radical is produced in the regions 10a, and the sensitizer Ps is produced from the sensitizer precursor Pp with use of the radical. Since the resist layer 10 contains the radical scavenger component Rk in the present embodiment, a portion of the produced radical is scavenged by the radical scavenger component Rk. Accordingly, the concentration distribution of the sensitizer Ps is sharp compared to that in the embodiments in which the resist layer 10 contains no radical scavenger component Rk.

Next, the flood exposure L2 is performed on the resist layer 10 as illustrated in FIG. 14C. Since the concentration distribution of the sensitizer Ps produced through the patterned exposure L1 is sharp, the concentration distribution of the acid Ac produced from the acid generator PAG with use of the sensitizer Ps can be sharp.

Next, the resist layer 10 is developed as illustrated in FIG. 14D. As described above, adding in advance a small amount of the radical scavenger component Rk to the resist layer 10 enables an improvement in contrast and resolution, inhibition of production of a small amount of acid as a result of the regions 10b being irradiated with stray light or out-of-band light, and an improvement in resist performance.

In the description given above with reference to FIGS. 10A to 10D and 11, the resist material contains the base component Bo. In the description given above with reference to FIG. 14A to 14D, the resist material contains the radical scavenger component Rk. However, the present invention is not limited to such configurations. The resist material may contain both the base component Bo and the radical scavenger component Rk.

Furthermore, the resist layer 10 may contain a radical generating component that is different from the acid generator PAG as mentioned above. Alternatively, the resist layer 10 may contain a radical generating component that is the same material as the acid generator PAG. In this case, the flood exposure L2 causes production of the acid generator PAG and production of the sensitizer Ps. This reaction includes a reaction associated with a radical, and therefore the resist layer 10 preferably contains the radical scavenger component Rk as described above. Furthermore, the resist layer 10 may contain a radical inhibitor generator that generates a radical scavenger component through exposure to light (for example, flood exposure).

In the description given above with reference to FIGS. 1A to 14D, the resist layer 10 is uncovered and in a direct contact with the external atmosphere. However, the present invention is not limited to such a configuration. The surface of the resist layer 10 may be provided with a topcoat layer. Furthermore, an underlayer may be provided between the resist layer 10 and the substrate S.

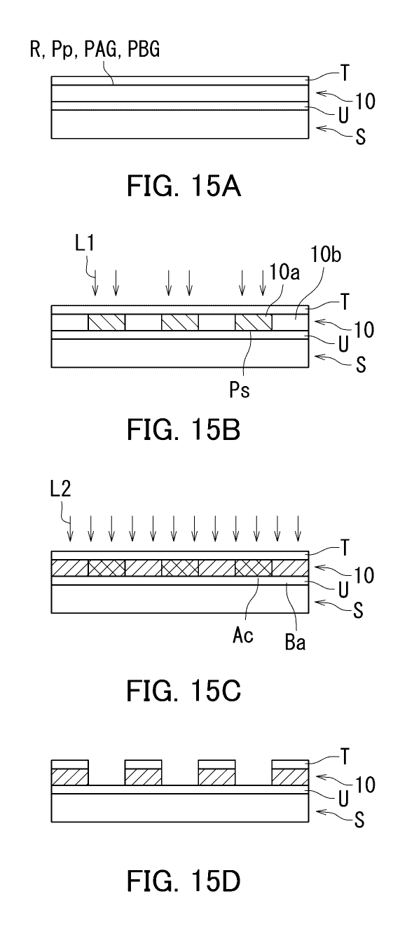

The following describes a resist patterning method according to an embodiment of the present invention with reference to FIGS. 15A to 15D. The resist patterning method according to the present embodiment is similar to the resist patterning method described with reference to FIGS. 1A to 1D and 2A to 2B except that a topcoat layer T is further formed on the surface of the resist layer 10. Accordingly, redundant description thereof is omitted in order to avoid repetition.

First, an underlayer U is formed on the substrate S as illustrated in FIG. 15A. The underlayer is for example formed from a commercially available inorganic material or organic material.

Next, the resist layer 10 is formed on the underlayer U. The resist layer 10 contains the base resin R, the sensitizer precursor Pp, the acid generator PAG, and the base generator PBG.

Next, the topcoat layer T is formed on the surface of the resist layer 10. The topcoat layer T blocks basic substances and/or oxygen from entering the resist layer 10. Preferably, the topcoat layer T transmits the beams for the patterned exposure L1 and the flood exposure L2, and blocks as many of out-of-band light beams as possible.

In a configuration in which the sensitizer precursor Pp is of acetal type, for example, the topcoat layer T is preferably impervious to basic compounds in order to prevent acid inactivation. In a configuration in which the sensitizer precursor Pp is of alcohol type, for example, the topcoat layer T is formed from a non-oxygen-permeable cross-linked polymer film or a polymer film containing an oxygen-reactive substance such as hydroquinone or 3,5-dibutyl-4-hydroxytoluene. The thickness of the topcoat layer T is determined according to a beam source for the patterned exposure L1. In a configuration in which EUV is used for the beam source, for example, the topcoat layer T preferably has a thickness of at least 20 nm and no greater than 50 nm, because large energy loss of the EUV is expected at the topcoat layer T. Furthermore, in a configuration in which an EB is used for the beam source, the topcoat layer T preferably has a thickness of no greater than 50 nm, although the thickness depends on the energy of the EB. Furthermore, in a configuration in which ArF or KrF is used for the beam source, the topcoat layer T is preferably transparent to the beam, and the topcoat layer T may have a thickness of at least 20 nm and no greater than 200 nm.

Next, the patterned exposure L1 is performed on the resist layer 10 through the topcoat layer T as illustrated in FIG. 15B. As described above, the sensitizer Ps is formed in the regions 10a through the patterned exposure L1.

Next, the flood exposure L2 is performed on the resist layer 10 through the topcoat layer T as illustrated in FIG. 15C. As described above, the acid Ac is formed in the regions 10a and the base Ba is formed in the regions 10b through the flood exposure L2.

Next, the resist layer 10 is developed as illustrated in FIG. 15D. As a result of the developing, the regions 10a in which the acid Ac has been produced (regions where the latent image has been formed) are removed by being dissolved in a developing solution. Through the above, the resist layer 10 having a pattern according to a pattern shape of the patterned exposure L1 can be formed. The topcoat layer T on the resist layer 10 may be removed as necessary after the patterned exposure L1 or after the flood exposure L2. During the patterned exposure L1 or during the flood exposure L2, the topcoat layer T provided as described above inhibits unintended entrance of basic substances and/or the radical scavenger component into the resist layer 10. Thus, the resist performance of the resist layer 10 is further improved.

In the description given above with reference to FIGS. 15A to 15D, the topcoat layer T is provided on top of the resist layer 10, and the underlayer U is provided under the resist layer 10. However, the present invention is not limited to such a configuration. The underlayer U may be disposed under the resist layer 10 without the topcoat layer T being provided. Alternatively, the topcoat layer T may be provided on top of the resist layer 10 without the underlayer U being provided.

Furthermore, the underlayer U preferably functions as an anti-reflection film for the beam for the flood exposure L2. The most suitable thickness of the underlayer U is determined according to the wavelength of the flood exposure L2.

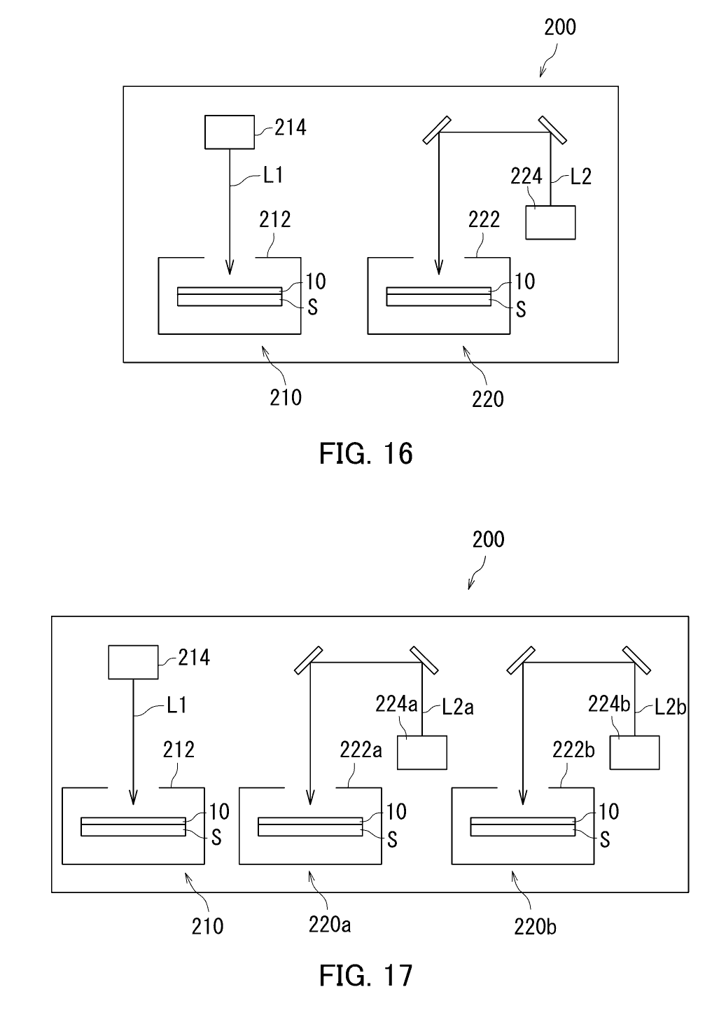

The patterned exposure and the flood exposure in the above-described resist patterning method are suitably performed in a latent resist image forming device. The following describes an embodiment of a latent resist image forming device 200 according to the present invention with reference to FIG. 16.

The latent resist image forming device 200 includes a patterned exposure device 210 and a flood exposure device 220. The patterned exposure device 210 performs the patterned exposure on the resist layer 10 formed on the substrate S. As described above, the resist layer 10 contains a base resin, a sensitizer precursor, an acid generator, and a base generator. The resist layer 10 may be formed directly on the substrate S or formed on another layer on the substrate S. The patterned exposure L1 performed by the patterned exposure device 210 causes production of a sensitizer from the sensitizer precursor in the resist layer 10. Next, the flood exposure device 220 performs the flood exposure L2 on the resist layer 10 to form a latent pattern image. The flood exposure L2 performed by the flood exposure device 220 causes production of an acid from the acid generator with use of the sensitizer and production of a base from the base generator.

The patterned exposure device 210 has a chamber 212 and a patterned exposure light source 214. The chamber 212 can accommodate the resist layer 10 formed on the substrate S. Preferably, the atmosphere inside the chamber 212 is an inert gas atmosphere, an active gas atmosphere, or a vacuum atmosphere. The active gas atmosphere for example includes hydrogen gas having a controlled partial pressure. Preferably, the chamber 212 is capable of controlling the temperature of the substrate S therein in a range of from −10° C. to 100° C.

The patterned exposure light source 214 emits a beam in a pattern shape to the resist layer 10 in the chamber 212. The beam from the patterned exposure light source 214 is electromagnetic waves such as visible light, UV, DUV, and EUV. Alternatively, the beam from the patterned exposure light source 214 may be an electron beam or an ion beam. The patterned exposure light source 214 for example includes an ion beam irradiation section, an electron beam irradiation section, or an electromagnetic wave irradiation section.

In a configuration in which an EUV light source is used as the light source for the patterned exposure L1, the EUV preferably has a wavelength of at least 1 nm and no greater than 13.5 nm, and more preferably at least 6 nm and no greater than 13.5 nm. Alternatively, in a configuration in which an electron beam is used as the beam for the patterned exposure L1, the electron beam preferably has an acceleration energy of at least 10 keV and no greater than 300 keV, and more preferably at least 40 keV and no greater than 130 keV.

In the present embodiment, the substrate S is conveyed from the patterned exposure device 210 to the flood exposure device 220 after the patterned exposure device 210 performs the patterned exposure on the resist layer 10 formed on the substrate S. While the substrate S is being conveyed from the patterned exposure device 210 to the flood exposure device 220, the atmosphere inside the latent resist image forming device 200 is preferably an inert gas atmosphere, an active gas atmosphere, or a vacuum atmosphere. In order to prevent acid inactivation during the period from the patterned exposure to the PEB, it is preferable to tightly control the atmosphere in the latent resist image forming device 200 using a basic compound removal filter or the like. Thus, decay of the activity of the resist layer 10 that is engendered by the patterned exposure device 210 can be inhibited. Preferably, the chamber 222 is capable of controlling the temperature of the substrate S therein in a range of from −10° C. to 100° C.

The flood exposure device 220 has a chamber 222 and a flood exposure light source 224. The chamber 222 can accommodate the resist layer 10 formed on the substrate S. Preferably, the atmosphere inside the chamber 222 is an inert gas atmosphere, an active gas atmosphere, or a vacuum atmosphere.

The flood exposure light source 224 emits the beam for the flood exposure L2 to the resist layer 10 in the chamber 222 to form a latent pattern image. The beam for the flood exposure L2 is for example electromagnetic waves such as visible light and UV. In FIG. 16, the beam for the flood exposure L2 is reflected off mirrors and guided into the chamber 222. The flood exposure light source 224 for example includes an ion beam irradiation section, an electron beam irradiation section, or an electromagnetic wave irradiation section.

The flood exposure device 220 may further have a mechanism for processing the beam into the shape of a certain area. The flood exposure device 220 for example has a projection lens system and a block mask. Alternatively, the flood exposure device 220 may have the block mask but no projection lens system. It is favorable that the flood exposure device 220 has only the block mask because the configuration thereof is simpler.

Thus, the patterned exposure light source 214 may emit a beam in a pattern shape within an area of the resist layer 10, and thereafter the flood exposure light source 224 may emit a beam over the area to form a predetermined latent pattern image in the resist layer 10. The patterned exposure light source 214 is a pattern irradiation source that emits a beam in a pattern shape, whereas the flood exposure light source 224 is an area irradiation source.

The resist layer 10 may be developed by a developing device, not shown, after the latent pattern image has been formed in the resist layer 10. As a result of the developing, the resist layer 10 having a predetermined pattern is obtained.

Preferably, the latent resist image forming device 200 for example further includes a coater/developer (not shown herein) in addition to the patterned exposure device 210 including the patterned exposure light source 214 and the flood exposure device 220 including the flood exposure light source 224. The latent resist image forming device 200 including the coater/developer forms a pattern in the resist layer 10 as described below. First, the coater/developer forms an under layer on the substrate S by spin coating and bakes the under layer.

Next, the coater/developer deposits the resist layer 10 on the under layer and pre-bakes the resist layer 10. As needed, another layer may be formed on the resist layer 10 by spin coating and the layer may be baked.

Next, the patterned exposure light source 214 of the patterned exposure device 210 emits the beam to the resist layer 10. Thereafter, the flood exposure light source 224 of the flood exposure device 220 emits the beam to the resist layer 10. Thus, the latent pattern image is formed in the resist layer 10.

Next, the coater/developer performs post-baking. Thereafter, the coater/developer develops the resist layer 10. Thus, the resist layer 10 having a predetermined pattern shape is formed. Next, the coater/developer rinses the resist layer 10 with purified water and performs post-baking (drying). Through the above, a pattern can be formed in the resist layer 10.

In a configuration in which the substrate S is conveyed between the coater/developer, a location where the resist layer 10 is activated, and a location where a latent pattern image is formed in the resist layer 10, the substrate S is preferably conveyed under a predetermined inert gas atmosphere, active gas atmosphere, or vacuum atmosphere. A stage having a temperature adjusting function is suitably used as the conveying member.

The coater/developer may be disposed within the chamber 212 of the patterned exposure device 210 or disposed within the chamber 222 of the flood exposure device 220. Furthermore, the coater/developer may be disposed in a chamber shared by the patterned exposure device 210 and the flood exposure device 220.

In the description given above with reference to FIG. 16, the resist layer 10 in the chamber 212 is irradiated with the beam emitted from the patterned exposure light source 214, and the resist layer 10 in the chamber 222 is irradiated with the beam emitted from a different light source from the patterned exposure light source 214, that is, the flood exposure light source 224. However, the present invention is not limited to such a configuration.

Furthermore, in the description given above with reference to FIG. 16, the substrate S is taken out from the chamber 212 and then conveyed to chamber 222 once the resist layer 10 formed on the substrate S has been activated. However, the present invention is not limited to such a configuration. The substrate S may be conveyed from the chamber 212 to the chamber 222 through a communication path providing communication between the chamber 212 and the chamber 222.

Furthermore, in the description given above with reference to FIG. 16, the patterned exposure device 210 and the flood exposure device 220 include the chamber 212 and the chamber 222, respectively. However, the present invention is not limited to such a configuration. The patterned exposure device 210 and the flood exposure device 220 may share a single chamber.

The latent resist image forming device 200 described above with reference to FIG. 16 has one flood exposure device 220. However, the present invention is not limited to such a configuration. The latent resist image forming device 200 may include a plurality of flood exposure devices that each emit a beam having a different wavelength. Alternatively, one flood exposure device may emit different beams.

Hereinafter, the latent resist image forming device 200 according to an embodiment of the present invention will be described with reference to FIG. 17. The latent resist image forming device 200 according to the present embodiment has a similar configuration to the latent resist image forming device described above with reference to FIG. 16 except including two flood exposure devices. Accordingly, redundant description thereof is omitted in order to avoid repetition.

The latent resist image forming device 200 includes the patterned exposure device 210, a first flood exposure device 220a, and a second flood exposure device 220b. The patterned exposure device 210 performs the patterned exposure L1 on the resist layer 10 formed on the substrate S, and subsequently the first flood exposure device 220a performs the first flood exposure L2a on the resist layer 10 and the second flood exposure device 220b performs the second flood exposure L2b on the resist layer 10 to form a latent pattern image.

The patterned exposure device 210 includes the chamber 212 and the patterned exposure light source 214. The patterned exposure light source 214 emits a beam in a pattern shape to the resist layer 10 in the chamber 212. The beam from the patterned exposure light source 214 is electromagnetic waves such as visible light, UV, DUV, and EUV. Alternatively, the beam from the patterned exposure light source 214 may be an electron beam or an ion beam.

The first flood exposure device 220a has a chamber 222a and a first flood exposure light source 224a. The chamber 222a can accommodate the resist layer 10 formed on the substrate S. Preferably, the atmosphere inside the chamber 222a is an inert gas atmosphere, an active gas atmosphere, or a vacuum atmosphere.

The substrate S is conveyed from the patterned exposure device 210 to the first flood exposure device 220a after the patterned exposure device 210 performs the patterned exposure on the resist layer 10 formed on the substrate S. While the substrate S is being conveyed from the patterned exposure device 210 to the first flood exposure device 220a, the atmosphere inside the latent resist image forming device 200 is preferably an inert gas atmosphere, an active gas atmosphere, or a vacuum atmosphere.

The first flood exposure light source 224a emits the beam for the first flood exposure L2a to the resist layer 10 in the chamber 222a. The beam emitted from the first flood exposure light source 224a is applied over an area within the resist layer 10. The beam for the first flood exposure L2a is for example electromagnetic waves such as visible light and UV. In FIG. 17, the beam for the first flood exposure L2a is reflected off mirrors and guided into the chamber 222a.

The substrate S is conveyed from the first flood exposure device 220a to the second flood exposure device 220b after the first flood exposure device 220a performs the first flood exposure L2a on the resist layer 10 formed on the substrate S. While the substrate S is being conveyed from the first flood exposure device 220a to the second flood exposure device 220b, the atmosphere inside the latent resist image forming device 200 is preferably an inert gas atmosphere, an active gas atmosphere, or a vacuum atmosphere.

The second flood exposure device 220b has a chamber 222b and a second flood exposure light source 224b. The chamber 222b can accommodate the resist layer 10 formed on the substrate S. Preferably, the atmosphere inside the chamber 222b is an inert gas atmosphere, an active gas atmosphere, or a vacuum atmosphere.

The second flood exposure light source 224b emits the beam for the second flood exposure L2b to the resist layer 10 in the chamber 222b to form a latent pattern image. The beam emitted from the second flood exposure light source 224b is applied over the area within the resist layer 10. The beam for the second flood exposure L2b is for example electromagnetic waves such as visible light and UV. In FIG. 17, the beam for the second flood exposure L2b is reflected off mirrors and guided into the chamber 222.

Preferably, the beam emitted by the second flood exposure light source 224b has a longer wavelength than the beam emitted by the first flood exposure light source 224a. However, the beam emitted by the second flood exposure light source 224b may have a shorter wavelength than the beam emitted by the first flood exposure light source 224a.

The resist layer 10 may be developed by a developing device, not shown, after the latent pattern image has been formed in the resist layer 10. As a result of the developing, the resist layer 10 having a predetermined pattern is obtained.

In the description given above with reference to FIG. 17, different types of flood exposure are performed by different devices, that is, the first flood exposure device 220a and the second flood exposure device 220b. However, the present invention is not limited to such a configuration. Both the first flood exposure L2a and the second flood exposure L2b may be performed using a single flood exposure light source of a flood exposure device.

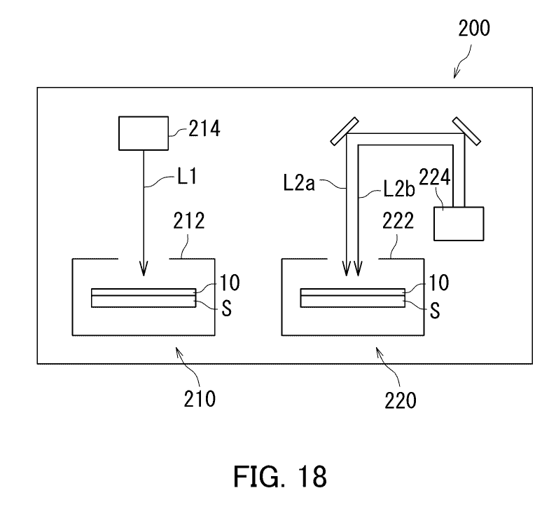

The following describes the latent resist image forming device 200 according to an embodiment of the present invention with reference to FIG. 18. The latent resist image forming device 200 according to the present embodiment has a similar configuration to the latent resist image forming device described with reference to FIG. 17 except that both the first flood exposure L2a and the second flood exposure L2b are performed using the single flood exposure light source 224 in the flood exposure device 220. Accordingly, redundant description thereof is omitted in order to avoid repetition.

The flood exposure device 220 has the chamber 222 and the flood exposure light source 224. The chamber 222 can accommodate the resist layer 10 formed on the substrate S. Preferably, the atmosphere inside the chamber 222 is an inert gas atmosphere, an active gas atmosphere, or a vacuum atmosphere.

The flood exposure light source 224 emits beams for the flood exposure L2 to the resist layer 10 in the chamber 222 to form a latent pattern image. The beams for the flood exposure L2 are for example electromagnetic waves such as visible light and UV

In the present embodiment, the flood exposure device 220 performs the first flood exposure L2a and the second flood exposure L2b. The flood exposure light source 224 emits the beam for the first flood exposure L2a to the resist layer 10 in the chamber 222. The beam emitted from the flood exposure light source 224 is applied over an area within the resist layer 10.

Thereafter, the flood exposure light source 224 emits the beam for the second flood exposure L2b to the resist layer 10 in the chamber 222. In the second flood exposure L2b, the beam emitted from the flood exposure light source 224 is also applied over the area within the resist layer 10. Typically, the beam for the second flood exposure L2b has a different wavelength from the beam for the first flood exposure L2a. As described above, both the first flood exposure L2a and the second flood exposure L2b may be performed using the single flood exposure light source 224 in the flood exposure device 220.

In the description given above, the flood exposure is performed after the patterned exposure. However, the present invention is not limited to such a configuration. Preliminary flood exposure may be performed prior to the patterned exposure. Alternatively, the production of the sensitizer Ps from the sensitizer precursor Pp does not need to be completed only by the patterned exposure, and flood exposure for production of the sensitizer Ps from the sensitizer precursor Pp may be performed after the patterned exposure.

In the description given above, the resist layer is a positive resist layer. However, the present invention is not limited to such a configuration. The resist layer may be a negative resist layer.

### EXAMPLE

The following describes an example of the present embodiment. Note that the present invention is not in any way limited to the example.

A resist material was prepared by adding 5 parts by mass of DPI-PFBS as the acid generator PAG, 5 parts by mass of DOBzMM as the sensitizer precursor Pp, and 1 part by mass of dicyclohexylammonium 2-(3-benzoylphenyl) propionate as the base generator PBG to 100 parts by mass of a methyl methacrylate-based polymer (hereinafter, referred to as “MMA”) dissolved in cyclohexanone. In the present example, DOBzMM was selected as the sensitizer precursor Pp and dicyclohexylammonium 2-(3-benzoylphenyl) propionate was selected as the base generator PBG such that the sensitizer precursor Pp and the base generator PBG would have relatively similar absorption wavelength spectra.

The thus prepared resist material was applied onto a hexamethyldisilazane (HMDS)-treated silicon substrate by spin coating at 1,000 rpm for 120 seconds using a spin coater (Mikasa Co., Ltd.). A thermal treatment was performed at 100° C. for 1 minute after the spin coating to form a resist layer. A thickness of the resist layer after the spin coating was measured using an AFM (NanoNavi II/SPA-300HV, product of Hitachi High-Tech Science) to be approximately 50 nm.

The resist layer was irradiated with an electron beam at an irradiation current of 12.5 pA and an acceleration voltage of 30 keV using a patterning device JSM-6500F (with a beam blanker, raster scanning), product of JEOL Ltd., as a patterned exposure device. After the patterned exposure, the resist layer was maintained in the atmosphere for one minute as an interval. Subsequently, flood exposure was performed. An LED light source (365 nm, LED LC-L5, product of Hamamatsu Photonics) was used as a flood exposure device. The resist layer was irradiated with ultraviolet in the atmosphere using the light source of 1.3 W/hour.

The flood exposure was followed by a thermal treatment at 100° C. for 60 seconds. Thereafter, the resist layer was developed at 24° C. for one minute using a 2.38% tetramethylammonium hydroxide (TMAH) developing solution.

The dose representing a sensitivity E₀ of the resist layer was 17 μC/cm² when the flood exposure was performed for one minute. The dose representing the sensitivity E₀ of the resist layer was 8 μC/cm² when the flood exposure was performed for two minutes. The dose representing the sensitivity E₀ of the resist layer decreased with increase in the ultraviolet exposure dose.

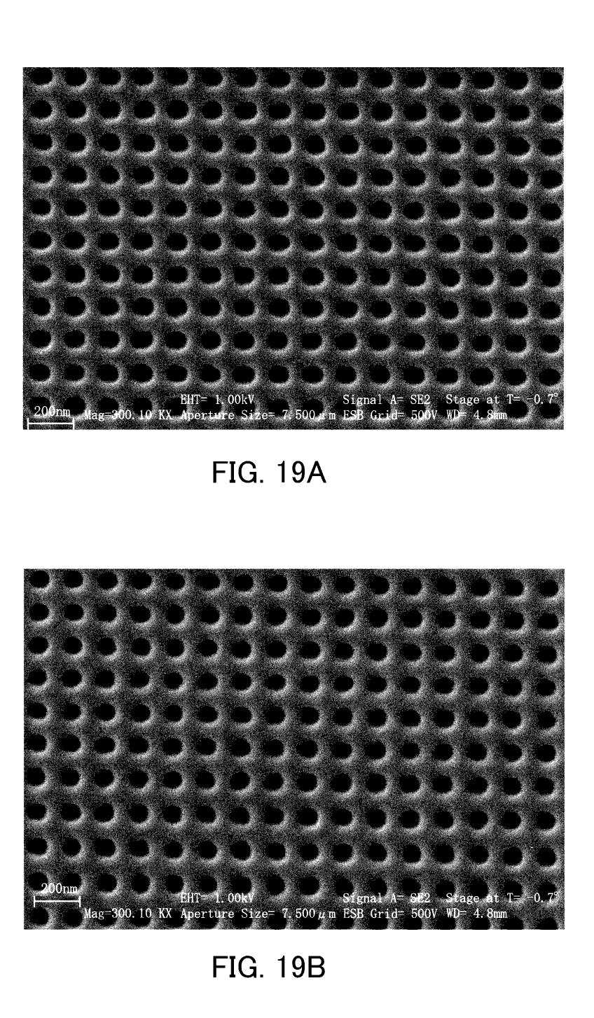

FIGS. 19A and 19B each show an SEM image of the resist layer subjected to the one-minute flood exposure after the patterned exposure. FIG. 19A shows the resist layer that was exposed, as the patterned exposure, to an electron beam at an exposure dose of 90 μC/cm² in a pattern of dots of 60 nm, subjected to the one-minute flood exposure, and subsequently developed. FIG. 19B shows the resist layer that was exposed, as the patterned exposure, to an electron beam at an exposure dose of 138 μC/cm² in a pattern of dots of 60 nm, subjected to the one-minute flood exposure, and subsequently developed. The pattern of dots was formed adequately in each of the resist layers.

For reference, a resist layer was formed using the same resist material as the resist material mentioned above under the same conditions for processes such as pre-baking, PEB, and developing as those mentioned above except that no ultraviolet irradiation was performed as the flood exposure. The dose representing the sensitivity E₀ of this resist layer was 36 μC/cm².

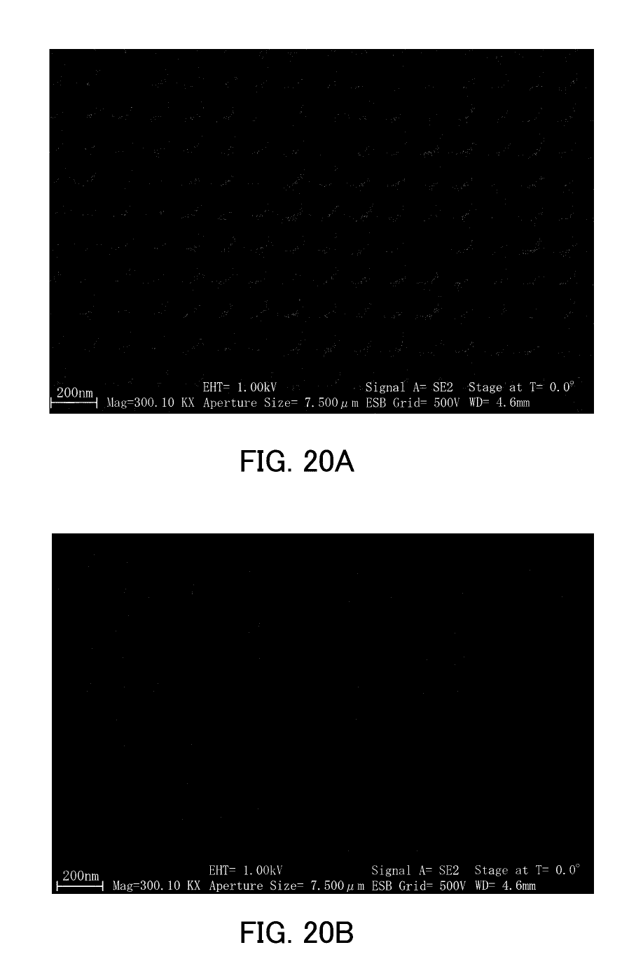

FIGS. 20A and 20B each show an SEM image of the resist layer on which the patterned exposure has been performed but the flood exposure has not been performed thereafter. FIG. 20A shows the resist layer that was exposed, as the patterned exposure, to an electron beam at an exposure dose of 240 μC/cm² in a pattern of dots of 93 nm and subsequently developed. FIG. 20B shows the resist layer that was exposed, as the patterned exposure, to an electron beam at an exposure dose of 300 μC/cm² in a pattern of dots of 100 nm and subsequently developed.

The resist layer shown in FIG. 20A had regions in which dots were not adequately formed due to the insufficient exposure dose. Furthermore, the resist layer shown in FIG. 20B also had regions in which dots were not adequately formed due to the slightly insufficient exposure dose. Note that in the case where only the patterned exposure using an electron beam was performed, even an exposure dose of 300 μC/cm² failed to enable adequate formation of the pattern of dots. Furthermore, an increase in the exposure dose from 240 μC/cm² to 300 μC/cm² led to a decrease in the resolution from 93 nm to 100 nm.

In the case where only the patterned exposure using an electron beam was performed, even an exposure dose of 300 μC/cm² failed to enable adequate formation of the pattern of dots. In contrast, in the case where the flood exposure was performed in addition to the patterned exposure using an electron beam, even an exposure dose of 90 μC/cm² enabled adequate formation of the pattern of dots, achieving a not less than three times higher sensitivity. Likewise, in the case where only the patterned exposure using an electron beam was performed, even the dot pattern of a resolution of 100 nm could not be formed adequately. In contrast, in the case where the flood exposure was performed in addition to the patterned exposure using an electron beam, the pattern of dots of a resolution of 60 nm could be formed adequately.

Furthermore, in the case where only the patterned exposure using such an electron beam exposure device as described above was performed, an increase in the dose of the beam spot led to a change in the dose of the beam, and therefore a decrease in the resolution was observed. In contrast, in the case where the flood exposure was performed in addition to the patterned exposure using the electron beam exposure device, the change in the dose of the beam could be restricted, preventing a decrease in the resolution.

Although it is impossible to directly measure the concentration distribution of the acid produced only through the patterned exposure, the concentration distribution of the acid can be estimated from the shape of the resist layer that was developed. The results shown by FIGS. 20A and 20B suggest that the concentration distribution of the acid has a similar shape to the concentration distribution of the sensitizer Ps shown in FIGS. 2A and 4A.

In contrast, the results shown by FIGS. 19A and 19B suggest that the concentration distribution of the acid produced through the patterned exposure and the flood exposure has a similar shape to the concentration distribution of the acid Ac shown in FIGS. 2B and 4C. As described above, it is thought that as a result of the flood exposure that was performed in addition to the patterned exposure, the concentration distribution of the acid changed from the concentration distribution similar to that of the sensitizer Ps shown in FIGS. 2A and 4A to the concentration distribution similar to that of the acid Ac shown in FIGS. 2B and 4C.

The present example achieved reduction of an influence of photon shot noise on the roughness as well as resolution improvement and sensitivity improvement at the same time while solving the trade-off of the resist between the sensitivity, the resolution, and the line width roughness (LWR).

The description given above takes, as an embodiment in which the sensitizer Ps is produced directly from the sensitizer precursor Pp in the patterned exposure step, an embodiment in which the sensitizer precursor Pp is directly ionized or excited through the patterned exposure L1 and thus the sensitizer precursor Pp is decomposed or isomerized to produce the sensitizer Ps, and an embodiment in which an electron produced in the resist layer 10 through the patterned exposure L1 reacts with the sensitizer precursor Pp to produce the sensitizer Ps. However, the present invention is not limited to such configurations. Furthermore, the description given above takes, as an embodiment in which the sensitizer Ps is produced indirectly from the sensitizer precursor Pp in the patterned exposure step, an embodiment in which the acid Ac and/or the radical are produced from the acid generator PAG through the patterned exposure L1 and the acid Ac and/or the radical react with the sensitizer precursor Pp to produce the sensitizer Ps. However, the present invention is not limited to such a configuration.

The sensitizer Ps excited through the flood exposure L2 may react with the acid generator PAG to produce the acid Ac and/or the radical, and the acid Ac and/or the radical may react with the sensitizer precursor Pp to produce the sensitizer Ps also in the flood exposure step. In the configuration in which the first flood exposure L2a and the second flood exposure L2b are performed as the flood exposure L2, for example, the sensitizer Ps excited through the first flood exposure L2a may react with the acid generator PAG to produce the acid Ac and/or the radical, and the acid Ac and/or the radical may react with the sensitizer precursor Pp to produce the sensitizer Ps.

In order to form a resist pattern achieving reduction of roughness due to photon shot noise as well as an improvement in the sensitivity of the resist layer while solving the trade-off between the sensitivity, the resolution, and the line width roughness (LWR) in the present embodiment, it is preferable to efficiently produce the sensitizer Ps in a small region through the patterned exposure L1 and to efficiently produce the acid Ac in the small region using the sensitizer Ps through the flood exposure L2 while reducing distribution roughness. To this end, it is preferable to take note of at least one of the following points (1) to (5).
(1) In order that the sensitizer Ps is produced to have a concentration distribution that is substantially similar to the intensity distribution of the beam for the patterned exposure L1, it is preferable to directly ionize or excite the sensitizer precursor Pp through the patterned exposure L1 and decompose and/or isomerize the sensitizer precursor Pp to produce the sensitizer Ps. As described above, the sensitizer Ps is preferably produced through direct ionization or excitation of the sensitizer precursor Pp.
(2) In a configuration in which the sensitizer precursor Pp reacts with a thermo-electron produced in the resist layer 10 through the patterned exposure L1 to directly produce the sensitizer Ps, the ionization product produced through the irradiation in the patterned exposure L1 has a concentration distribution that is substantially similar to the intensity distribution of the beam for the patterned exposure L1. However, the thermalization length of the electron produced from the ionization product is several nanometers. Furthermore, the frequency of the reaction between the thermalized electron and the sensitizer precursor Pp depends on the concentration of the sensitizer precursor Pp, and the length of the reaction is typically several nanometers. Accordingly, the sensitizer Ps produced with use of the ionization product has a concentration distribution that is slightly wider than the intensity distribution of the beam for the patterned exposure L1.
(3) The acid Ac and/or the radical are produced from the acid generator PAG through the patterned exposure L1, and the sensitizer precursor Pp reacts with the acid Ac and/or the radical to produce the sensitizer Ps. In such a configuration, the acid Ac and/or the radical are produced at a point several nanometers away from the ionization product produced through irradiation in the patterned exposure L1. The reaction between the acid Ac and/or the radical and the sensitizer precursor Pp depends on the concentration of the sensitizer precursor Pp, and the length of the reaction is several nanometers. Accordingly, the sensitizer Ps has a concentration distribution that is slightly wider than the intensity distribution of the beam for the patterned exposure L1.
(4) The sensitizer Ps excited through the flood exposure L2 reacts with the acid generator PAG to produce the acid Ac and/or the radical, and the sensitizer precursor Pp reacts with the acid Ac and/or the radical to produce the sensitizer Ps in the flood exposure step. The reaction between the excited sensitizer Ps and the acid generator PAG to produce the acid Ac and/or the radical is electron transfer or energy transfer from the excited sensitizer Ps to the acid generator PAG, and the reaction starts as a substantially isotropic reaction that is highly distance-dependent in three-dimensional space. Accordingly, the acid Ac and/or the radical are produced in a sphere around the exited sensitizer Ps. In contrast, the reaction between the produced acid Ac and/or the radical and the sensitizer precursor Pp to produce the sensitizer Ps is triggered by thermal diffusion or collision of the acid Ac and/or the radical. Accordingly, the sensitizer Ps is produced along random diffusion paths of the acid and the radical.
(5) It is preferable that the excited sensitizer Ps and the acid generator PAG are selected so that the acid formation reaction is efficiently promoted through the three-dimensional and highly isotropic electron transfer or energy transfer reaction from the exited sensitizer Ps to the acid generator PAG, and the concentration of the acid generator PAG is high. Furthermore, it is effective for reducing roughness or photon shot noise-induced roughness that the proportion of the acid formation reaction promoted by the three-dimensional and highly isotropic electron transfer or energy transfer reaction is larger than the proportion of the reaction along random diffusion paths of the acid Ac and/or the radical.

In the description given above, the resist is a chemically amplified positive resist. However, the present invention is not limited to such a configuration. For example, a chemically amplified negative resist may be formed by performing a modification process accompanied by negative-tone development (NTD) on a conventional chemically amplified positive resist.

In the description given above, the resist is a chemically amplified resist. However, the present invention is not limited to such a configuration. The resist may be a non-chemically amplified resist. According to an embodiment of the present invention, the resist layer 10 may be a non-chemically amplified resist, and the resist layer 10 may be a nanoparticle resist in which the base resin R is a metal oxide. The metal of the metal oxide is for example Hf or Zr. In such an embodiment, the sensitizer Ps is produced from the sensitizer precursor Pp through the patterned exposure L1, and the sensitizer Ps excited by the flood exposure L2 promotes a reaction of the nanoparticles of the metal oxide to sensitize the resist. Needless to say, the present invention is not in any way limited to such an embodiment. A metal oxide nanoparticle resist containing the acid generator PAG is preferable because the base generator PBG is used independently or together with a photoreaction inhibitor generator therein.

### INDUSTRIAL APPLICABILITY

The resist patterning methods, the latent resist image forming devices, and the resist materials according to the present invention are suitably used in an exposure process of forming a resist pattern on a substrate. According to the resist patterning methods, the latent resist image forming devices, and the resist materials of the present invention, increased resist layer sensitivity can be achieved.

1. A resist patterning method, comprising:
a resist layer forming step of forming, on a substrate, a resist layer containing a base resin, a sensitizer precursor, an acid generator, and a base generator;
a patterned exposure step of performing patterned exposure on the resist layer to produce a sensitizer from the sensitizer precursor;
a flood exposure step of performing flood exposure on the resist layer in which the sensitizer has been produced to produce an acid from the acid generator and produce a base from the base generator after the patterned exposure; and
a developing step of developing the resist layer after the flood exposure.

2. The resist patterning method according to claim 1, wherein the flood exposure step includes:
a first flood exposure step of performing first flood exposure through which the sensitizer is excited, and the acid is produced through a reaction between the excited sensitizer and the acid generator; and
a second flood exposure step of performing second flood exposure through which the base is produced from the base generator.

3. The resist patterning method according to claim 1, wherein
in the patterned exposure step, the sensitizer is produced through structural transformation of the sensitizer precursor as a result of the patterned exposure, or the sensitizer is produced through a reaction between an electron generated in the resist layer and the sensitizer precursor.

4. The resist patterning method according to claim 1, wherein
in the patterned exposure step, the sensitizer is produced through a reaction between the sensitizer precursor and an acid produced from the acid generator through the patterned exposure, and
in the flood exposure step, the acid is produced from the acid generator with use of the sensitizer excited through the flood exposure.

5. The resist patterning method according to claim 4, wherein
in the patterned exposure step, the sensitizer is produced in association with diffusion of the acid.

6. The resist patterning method according to claim 4, wherein
in the patterned exposure step, the sensitizer precursor has either or both of sensitizing action on a reaction that produces the sensitizer from the sensitizer precursor and sensitizing action on a reaction that produces the acid from the acid generator.

7. The resist patterning method according to claim 4, wherein
in the resist layer forming step, the resist layer contains a base component.

8. The resist patterning method according to claim 7, wherein
in the patterned exposure step, spatial distribution of the sensitizer is controlled by controlling a diffusion coefficient of the acid and a diffusion coefficient of the base component, and
in the flood exposure step, spatial distribution of the acid is controlled based on the spatial distribution of the sensitizer.

9. The resist patterning method according to claim 7, wherein
in the patterned exposure step, the acid reacts with the base component to newly produce the acid generator.

10. The resist patterning method according to claim 7, wherein
in the patterned exposure step, the acid reacts with the base component to produce a different acid generator than the acid generator contained in the resist layer.

11. The resist patterning method according to claim 7, wherein
in the patterned exposure step, the base component is decomposed through the patterned exposure.

12. The resist patterning method according to claim 2, wherein
in the resist layer forming step, the resist layer contains a base component, and
in at least one of the patterned exposure step and the first flood exposure step, the base component is decomposed through at least one of the patterned exposure and the first flood exposure.

13. The resist patterning method according to claim 7, wherein
in the flood exposure step, the sensitizer is excited by the flood exposure, and the base component is decomposed by the excited sensitizer.

14. The resist patterning method according to claim 1, wherein
in the resist layer forming step, the resist layer contains a radical generating component, and
in the patterned exposure step, the sensitizer is produced from the sensitizer precursor with use of a radical produced from the radical generating component through the patterned exposure.

15. The resist patterning method according to claim 14, wherein
in the patterned exposure step, the sensitizer is produced in association with diffusion of the radical.

16. The resist patterning method according to claim 1, wherein
in the flood exposure step, the acid is produced in association with either or both of electron transfer and energy transfer from the sensitizer in an excited state to the acid generator.

17. The resist patterning method according to claim 1, wherein
in the flood exposure step, the acid has a substantially constant peak concentration throughout a region that is, of the resist layer, subjected to both the patterned exposure and the flood exposure.

18. The resist patterning method according to claim 1, wherein
in the flood exposure step, the base has a substantially constant peak concentration throughout a region on which, of the resist layer, the flood exposure has been performed but the patterned exposure has not been performed.

19. The resist patterning method according to claim 1, further comprising
a modification step of performing a modification treatment for transforming the resist layer from a positive type to a negative type or vice versa after the flood exposure step.

20. The resist patterning method according to claim 1, wherein
in the resist layer forming step, the resist layer is a non-chemically amplified resist layer.

21. The resist patterning method according to claim 1, further comprising
an underlayer forming step of forming an underlayer between the resist layer and the substrate.

22. The resist patterning method according to claim 1, further comprising
a topcoat forming step of forming a topcoat on the resist layer.

23-28. (canceled)

29. A resist material comprising a resist composition containing a base resin, a sensitizer precursor, an acid generator, and a base generator.

30. The resist material according to claim 29, wherein
the resist composition contains a base component.

31. The resist material according to claim 29, wherein
the resist composition contains a radical scavenger component.
